(19) United States
(12) Patent Application Publication
(10) Pub. No.: US 2024/0319304 A1
(43) Pub. Date: Sep. 26, 2024

(54) SINGLE SPIN NMR MEASUREMENT SYSTEMS AND METHODS

(71) Applicant: B. G. NEGEV TECHNOLOGIES AND APPLICATIONS LTD., Be'er-Sheva (IL)

(72) Inventor: Yishay MANASSEN, Be’er Sheva (IL)

(73) Assignee: B. G. NEGEV TECHNOLOGIES AND APPLICATIONS LTD., Be'er-Sheva (IL)

(21) Appl. No.: 18/278,368

(22) PCT Filed: Feb. 23, 2022
(86) PCT No.: PCT/IL2022/050212

§ 371 Date: Aug. 22, 2023

Related U.S. Application Data
(60) Provisional application No. 62/152,342, filed on Apr. 24, 2015.

(51) Int. Cl. G01R 33/60; G01N 24/10; G01Q 60/10

(52) U.S. Cl. CPC G01R 33/60; G01N 24/10; G01Q 60/10

(57) ABSTRACT

Detection of spin nucleus resonance (NMR) precession signal/peak of at least one atom or molecule of a sample material placed on a sample electrode while a static uniform magnetic field of a determined strength is induced through it is achieved by applying an alternating bias voltage to a tunneling tip in a frequency at least greater than an NMR frequency range and smaller than a hyperfine electron spin resonance (ESR) frequency range for alternatingly changing within each cycle of the alternating bias voltage at least one atom or molecule of a sample material between diamagnetic and paramagnetic states, and analysing a measured electrical tunneling current passing through the sample electrode. A plurality of hyperfine ESR signals/peaks are identified in the measured electrical tunneling current, each of which associated with a respective cycle of the alternating bias voltage, and a respective hyperfine ESR frequency thereof is determined.

### TECHNOLOGICAL FIELD

The present application is generally in the field of nuclear magnetic resonance (NMR) spectroscopy and particularly relates to excitation and detection of single spin NMR precession signals by a tunneling tip, such as used in scanning tunneling microscopes (STMs).

### BACKGROUND

This section intends to provide background information concerning the present application, which is not necessarily prior art. The following references are considered as background to the presently disclosed subject matter:
[1] Y. Manassen, E. Ter Ovanesyan, D. Shachal and S. Richter, “ESR-STM Experiments on thermally oxidized Si(111)”, Phys. Rev. B 48, 4887 (1993).
[2] A. V. Balatsky, M. Nishijima and Y. Manassen, “ESR-STM” Adv. Phys.61, 117 (2012).
[3] Y. Manassen, M. Averbukh, and M. Morgenstern, “Analysing multiple encounter as a possible origin of ESR signals in STM on Si(111) featuring C and O defects”, Surf. Sci. 623, 47 (2014).
[4] Y. Manassen, M. Averbukh, M. Jbara, B, Siebenhofer, A. Shnirman and B. Horovitz, “Fingerprints of single nuclear spin energy levels using STM-Endor” J. Magn. Reson. 289, 107 (2018).
[5] S. Baumann, W. Paul, T. Choi, C. P. Lutz, A. Ardavan and A. Heinrich, “Electron Paramagnetic Resonance of individual atoms on a surface”, Science 350, 417 (2015).
[6] K. Yang, Ph. Willke, Y. Bae, A. Ferron, J. Lado, A. Ardavan, J. Fernandez-Rossier, A. Heinrich and Ch. Lutz, APS meeting (2019).
[7] C. Muller et al, Nat. Commun. “Nuclear magnetic resonance spectroscopy with single spin sensitivity” Nat. Comm 5, 4703 (2014).
[8] J. J. Pla, K. Y. Tan, J. P. Dehollain, W. H. Lim, J. J. Morton, F. A. Zwanenburg, D. N. Jamieson, A. S. Dzurak and A. Morello, “High-Fidelity readout and control of a nuclear spin qubit in silicon”, Nature, 496, 334 (2013).
[9] K. Yang, Ph. Willke, Y. Bae, A. Ferron, J. L. Lado, A. Ardavan J. Fernandez Rossier, A. J. Heinrich and C. P. Lutz, “Electrically controlled nuclear polarization of individual atoms”, Nat. Nanotech. 13, 1120 (2018).
[10] R. Z. Bakhtizin, T. Hashizume, X. D. Wang. T. Sakurai, “Scanning tunneling microscopy of fullerenes on metal and semiconductor surfaces” Physics Uspekhi 40 275, (1997).
[11] J. Cho, J. Smerdon, L. Gao, Ö. Süzer, J. R. Guest, and N. P. Guisinger, “Structural and Electronic Decoupling of 60C from epitaxial graphene on SiC” Nano Lett. 12, 3018, (2012).
[12] “The effect of shift reagents on the NMR spectra of polyglycols—dimethylethers and cyclic polyethers”, PhD thesis A. M. Grotens.
[13] Y. Manassen, M. Averbukh, Z. Hazan, P. Boscolo, B. Piuzi, B. Horovitz “Single spin NMR (NMR1)”, ATTRACT 2019/05.

NMR phenomena is used in NMR spectroscopy inter alia to study molecular physics and crystals/non-crystalline materials. NMR spectroscopy techniques can be used to determine molecular structure and identify relatively large volumes of homogenous molecules, examine material depletion/formation, and characterize impurities, through precise measurement of nuclear spin resonance signals obtained from the examined matter under application of uniform magnetic field. The spectrum obtained currently utilizing such NMR spectroscopy techniques is of all the molecules that are examined. In contrast NMR imaging can provide spatial resolution that it is limited to 1 micron, but normally the high resolution NMR spectrum required to identify molecules do not exist in NMR imaging.

Macroscopic nuclear magnetic resonance (NMR) is by far the most comprehensive technique for chemical analysis. Each nucleus has a gyromagnetic ratio (γ) that is giving resonance at a very narrow frequency range. The only element that does not have a stable NMR detectable isotope is Argon (Ar). It is thus now appreciated that single spin NMR can be used to identify chemical elements of examined atoms. Moreover, it is possible to get a detailed NMR spectrum for distinguishing the chemical environment of the same atom and/or determining changes of its nucleus. Macroscopic NMR however requires at least 10¹⁵ molecules for a measurement. NMR imaging techniques are used for medicinal applications that can achieve a spatial resolution of the order of several microns.

The best way currently available to detect a single spin NMR precession signal is through a single spin electron resonance (if the electron is coupled to the nucleus). There are today many STM studies on single spin electron spin resonance (ESR) [1-5]. An experiment was reported in the 2019 APS meeting in which spin polarized current was used for NMR detection [6]. The reported technique did not require spin polarized tunneling, so use of high magnetic field was not required, nor cryogenic temperature and/or uniform radio-frequency (RF) irradiation at a broad frequency range.

Single spin NMR experiments show that the sensitivity of Nitrogen-vacancy (NV) centers [7] as a sensor for very small changes in a magnetic field, have reached to the level that single spin NMR can be detected. However, the position of the NV center is random, and no information is provided on the single spin environment.

High throughput screening of catalyst libraries using spin resonance techniques, and an evanescent wave probe, are disclosed in US Patent publication No. 2006/160136. The probe may operate using either nuclear magnetic resonance or electron spin resonance techniques. In one configuration, a scanning evanescent wave spin resonance probe is used in conjunction with a library of catalysts or other materials, and localized detection of spin resonance is carried out at each library address. In another configuration, the evanescent wave probe is used in a micro-reactor array assay.

### General Description

The present application provides techniques and setups for measuring NMR precession signals of a single atom/molecule in an electrical tunneling current between a tunneling tip and a sample electrode (due to quantum tunneling phenomena). The tunneling tip is configured to cause fast sequential ionization of the examined atom/molecule with anisotropic hyperfine interaction e.g., due to bias voltage modulation, resulting in temporal transformations of the examined atom/molecule between diamagnetic and paramagnetic states. A fast sequence of bias voltage pulses is applied in some embodiments to the tunneling tip to cause the ionization. A static magnetic field is induced through the sample in addition to the anisotropic hyperfine interaction. The magnetic field applied is maintained constant in all NMR measurement cycles. The anisotropic hyperfine interaction is an internal property of the measured molecule/atom.

The effective magnetic field on the nucleus of the examined atom/molecule (in the diamagnetic state) and on an unpaired electron thereof (in the paramagnetic state) are not parallel, such that the precession of the nucleus/atoms in the diamagnetic state is modulating the polarization of the hyperfine states and the matrix elements for the hyperfine transitions.

The single spin NMR techniques and setups disclosed herein can work both on magnetic and non-magnetic molecules, so they can be used to identify the chemical elements of all atoms when having an NMR active nucleus, except for Argon (Ar). An NMR spectrum was observed by the inventor hereof in ¹⁴N nucleus in a TEMPO molecule ((2,2,6,6-tetramethylpiperidin-1-yl)oxidanyl) on gold covered with graphene oxide [13], and of ¹H nuclei in toluene deposited on a clean gold substrate [13].

The term tunneling tip used herein to refer to an atomically sharp and stable tip (e.g., high-resolution minitip having radii smaller than 100 Å) made from electrically conducting and/or semi-conducting materials. Preferably, but need not necessarily, the tunneling tip is made from an electrically conducting material such as used in STM systems (e.g., a tungsten tip, such as used for ultra high vacuum measurements, or a platinum iridium tip, such as used in measurements on air.

The tunneling tip in the embodiments disclosed herein is configured to cause sequential ionization of the examined atom/molecule by application of a pulsating/alternating bias voltage thereto within very short time intervals (e.g., in a range of several tens of nanoseconds and up to few microseconds. Optionally, but in some embodiments preferably, a modulated/alternating bias voltage is applied to the tunneling tip in a frequency greater than the NMR frequency range (e.g., greater than 1 MHZ, if determined according to hydrogen with external magnetic field of 230 Gauss) and smaller than the ESR frequency range (e.g., smaller than 627 MHZ, if determined according to hydrogen with external magnetic field of 230 Gauss). Optionally, but in some embodiments preferably, the frequency of the alternating bias voltage is greater than the twice (factor of 2), or three time (factor of 3), the NMR spin precession frequency of hydrogen (i.e., greater than 2 or 3 MHZ), and smaller than 1/20 the ESR spin precession frequency of hydrogen (i.e., smaller than 31 MHZ). Within this frequency range of the alternating bias voltage applied to the tunneling tip the nucleus of the examined atom is considered to be quasi stationary within the short paramagnetic period, which results in a certain amplitude of the hyperfine peak, which thereby cause NMR/ESR signal excitation and enable accurate detection thereof. In the next paramagnetic period the ESR peak will have a slightly different amplitude due to the slightly different position of the nucleus, in accordance with its Larmor frequency.

In a broad aspect the subject matter disclosed herein is directed to a single spin NMR detector configured to apply an alternating bias voltage to a tunneling tip placed in close vicinity (e.g., few Angstrom [Å]) to sample material, measure a tunneling current passing through a sample electrode carrying the sample material and detect a plurality of hyperfine ESR precession signals/peaks therein, each associated with a cycle of the alternating bias voltage and reflects the temporal phase of the nuclear (NMR), that can be detected based on changes in the strength of the measured hyperfine ESR precession signals/peaks.

Accordingly, the single spin NMR precession measurement techniques disclosed herein utilize a plurality of hyperfine ESR measurements, each associated with a cycle of the alternating bias voltage (also referred to herein as ionization or ESR cycle), and at least one single spin NMR measurement cycle (also referred to herein as NMR cycle) associated with a plurality of the ESR cycles e.g., recorded using one hyperfine peak frequency.

The hyperfine ESR signals/peaks, and their respective hyperfine ESR frequencies, can be detected in the tunneling current utilizing one or more filters and/or peak (e.g., envelope) detectors. Alternatively, or additionally, spectral decomposition tools (e.g., fast Fourier transform—FFT) are used to identify the hyperfine ESR precession signals/peaks and their respective hyperfine ESR frequencies in the measured tunneling current.

The ESR-STM signal can be detected by a power spectrum analysis of the tunnelling current e.g., using a spectrum analyser e.g., KEYSIGHT's N9000B CXA. The spectrum analyser requires an impedance matching circuit configured to match the impedance of the tunnelling junction (e.g., 108 Ohm) to 50 Ohm. However, the spectrum analyser is an expensive device, and it is not necessary for single hyperfine frequency measurements. The hyperfine ESR signals is typically detected as elevated noise in the tunnelling current at the ESR precession frequencies. In possible embodiments the RF noise is removed from the DC tunnelling current by a bias “T”-device. An impedance matching circuit can be used to reduce the mismatch between the tunnelling junction and 50 ohm impedance of a RF amplifier used to amplify the measured tunnelling current e.g., by about 40-50 decibels of the RF signal, which is then processed by the spectrum analyser.

The single spin NMR detector is configured in some embodiments to adjust the strength of magnetic field induced through the sample material, and/or the frequency of the alternating bias voltage applied to the tunnelling tip, for tuning the measurements such that the ratio between the frequencies of the detected hyperfine ESR precession signals/peaks and of the bias tunnelling voltage is an integer number i.e., to guarantee that the frequency of the alternating bias voltage equals to a multiplication of the frequency of the hyperfine ESR signals/peaks by a number that is substantially a whole positive number.

Accordingly, in some embodiments the single spin NMR precession signal detector comprises a tuneable magnetic field applicator (e.g., tuneable electromagnet) configured to controllably apply a static magnetic field of a desired strength through the sample, or a magnetic field of a gradually changing strength for carrying out initialization/tuning actions before conducting the NMR measurement cycles i.e., the magnetic field induced through the sample can be changed in order to find an optimal hyperfine peak/signal which hyperfine frequency is to be used for the NMR detection. The initialization step can be used for examining unknown samples, for which the ESR hyperfine peak/signal frequency is unknown. Particularly, using the tuneable magnetic field with the detection/recording of the ESR signals/peaks at a certain frequency while applying the alternating bias voltage (modulation) with the appropriate frequency, the NMR spectrum of the paramagnetic atom or molecule can be observed through the intensity of the ESR signal as a function of the applied magnetic field.

The single spin NMR precession signal detector can be accordingly configured to perform an initialization/tuning stage in which the magnetic field induced through the sample is gradually changed/scanned (e.g., between 0 to 400 Gauss, optionally between 250 to 400 or 600 Gauss. It is noted that the external magnetic field induced through the sample should not be much larger than (or in the order of) the magnetic field of the anisotropic hyperfine splitting. In the initialization/tuning stage the externally applied magnetic field can be scanned between one or more consecutive ESR cycles in which the alternating bias voltage is applied to the tunneling tip in a fixed predetermined frequency, and the hyperfine ESR precession signals/peaks detected in the tunneling current are analysed to determine therefrom hyperfine ESR frequencies of one or more strong hyperfine ESR precession signals/peaks (i.e., clearly distinguishable peaks), or of hyperfine ESR precession signals/peaks having maximal strength/magnitude. i.e., the strength of the external magnetic field induced through the sample is gradually changed until a strong/clear ESR peak is detected, or to find the external magnetic field strength for which a detected ESR signal/peak is of maximal strength.

In embodiments hereof strong/distinguishable single spin NMR precession signals/peaks can be observed in the tunneling current when the ratio of the frequencies of the hyperfine ESR precession signals/peaks and of the alternating bias voltage substantially equals a positive whole number (within the defined precision). One or more of the strengths of the magnetic field induced through the sample when the strong (or maximal strength) hyperfine ESR precession signals/peaks are detected in the tunneling current, and their respective hyperfine ESR frequencies, are recorded for use in the NMR measurement cycles. The hyperfine frequency for which a maximal ESR peak is measured is sometimes referred to herein as the optimal hyperfine frequency. The hyperfine frequencies for which strong (not necessarily maximal) hyperfine ESR precession signals/peaks are detected in the tunneling current are sometimes referred to herein as observable hyperfine frequencies

For example, when a spectrum analyser is used to process the tunnelling current, if the optimal hyperfine frequency is unknown, it is possible to change the frequency used by the spectrum analyser, and/or the frequency of the alternating bias voltage modulation, in the condition that the ratio between these two frequencies (i.e., being an integer number) is not changing. In this way it is possible to find the ESR-STM spectrum of a molecule which is unknown. Alternatively, in possible embodiments the strength of the external magnetic field is scanned to find an observable or optimal hyperfine frequency, to carry out NMR measurement cycles keeping the hyperfine and the modulation frequencies constant e.g., to observe an ESR-STM of unknown molecule.

After the initialization stage, one or more NMR measurement cycles are performed while inducing a static/fixed magnetic field at one or more of the strengths recorded for the strong (or maximal strength) hyperfine ESR precession signals/peaks detected in the tunneling current during the initialization stage. Optionally, but in some embodiments preferably, at least some of the components of the single spin NMR detector are adjusted/tuned in accordance with at least one of the hyperfine ESR frequencies recorded in the initialization stage. Particularly, components of the single spin NMR detector are adjusted to the optimal (or an observable) hyperfine ESR frequency associated with a magnetic field strength recorded in the initialization stage and being induced through the sample to measure the single spin NMR precession signals/peaks.

For example, and without being limiting, in some embodiments the tunneling current is filtered during the NMR measurement cycles by one or more filters (e.g., band pass filter), which are tuned to the hyperfine ESR frequency associated with the magnetic field strength induced through the sample during the NMR measurement cycle, as recorded in the initialization stage (e.g., the optimal, or an observable, hyperfine frequency). In addition, in embodiments wherein the filtered tunneling current is demodulated, the demodulator is also tuned to the (e.g., optimal or observable) hyperfine ESR frequency associated with the magnetic field strength induced through the sample during the NMR measurement cycle, as recorded in the initialization stage.

Optionally, the hyperfine frequency used for the ESR measurement and the frequency of the alternating bias voltage are kept constant and the externally applied magnetic field is changed such that the ESR hyperfine frequency is obtained on a chosen hyperfine peak frequency.

In possible embodiments, instead of scanning the strength of the externally applied magnetic field, the frequency of the alternating bias voltage is scanned during the initialization stage, while a static/fixed magnetic field of a predefined strength is induced through the sample. The initialization stage is performed in such embodiments as described hereinabove or hereinbelow, but for each strong/maximal strength hyperfine ESR signal/peak detected therein the respective frequencies of the alternating bias voltage and of the detected strong/maximal strength hyperfine ESR signal/peak associated therewith are recorded. Namely, in the initialization stage in this case (i.e., when the externally applied magnetic field is kept constant) the frequency of the alternating biasing voltage is continuously changed/scanned for ESR signal/peak detection, and afterwards the NMR precession signal measurement is carried out in the frequencies found in the scan. As described above, the ratio between the hyperfine frequency and the bias modulation frequency should be an integer number.

In such embodiments the NMR measurement cycles are performed while inducing the same static/fixed magnetic field having the predefined strength used in the initialization stage, and while applying the alternating bias voltage in at least one of the alternating bias voltage frequencies recorded during the initialization stage i.e., while guaranteeing that the ratio between the hyperfine peak frequency and the alternating bias voltage modulation frequency is an integer number. Components of the single spin NMR detector can be similarly adjusted in the NMR measurement cycles in accordance with the hyperfine ESR frequency associated with the frequency of the alternating bias voltage, as recorded in the initialization stage. In this case, however, further impedance matching steps may be required to tune the equipment (e.g., RF amplifier) of the single spin NMR detector to the frequency of the alternating bias voltage used in the NMR measurement cycles.

In some possible embodiments the tunneling tip of the single spin NMR detector is part of a conventional STM system. Accordingly, embodiments disclosed herein are also directed to NMR-STM systems comprising a conventional STM system and the single spin NMR precession signal detector disclosed hereinabove or hereinbelow. Such NMR-STM system embodiments can be advantageously configured to concurrently acquire atomic level imaging and single spin NMR precession signals to provide NMR signal mapping for each pixel in the atomic level image generated by the STM system. Namely, the tunneling current used for atomic level image construction of each atom of the sample can be concurrently (or shortly thereafter) used for the NMR measurement cycles at the same position of the tunneling tip in close proximity to the examined atom.

The embodiments disclosed herein are thus also directed to composite STM images configured to present mapping of single spin NMR signals/peaks (or related spectroscopic properties) of atoms/molecules of an examined sample on top of the atomic level image of the sample (or vice versa) produced by the STM system. The disclosed embodiments are also directed to methods/techniques for excitation of single spin NMR precession signals utilizing RF pulses (together with the alternating bias voltage), and measurement thereof in the tunnelling current affected by a tunnelling tip. As will be explained in the detailed description, the methods disclosed herein are able to observe high resolution NMR spectrums that can be used to identify a molecule located under the tunneling tip.

NMR spectrum detection of a single molecule/atom utilizing embodiments disclosed herein can take about one (1) second, or less (without initialization). Thus, it is possible to obtain the NMR detection spectrum data/signals within the regular time scales required for STM system measurement of the atom/molecule (if the molecule/atom are known to begin with). In the case the initialization sage is required (i.e., if an unknown atom/molecule is inspected) to find hyperfine ESR signal/peak frequencies, a slower scan procedure (initialization stage) is required e.g., of about 30 seconds for each pixel, because usually the linewidth of the hyperfine peak is large, such that less points are necessary in the initialization stage.

In one aspect the present application is directed to a single spin nucleus resonance (NMR) detector comprising: a pulse generator configured to apply an alternating bias voltage to a tunneling tip in a frequency at least greater than an NMR frequency range and smaller than a hyperfine electron spin resonance (ESR) frequency range for alternatingly changing within each cycle of the alternating bias voltage at least one atom or molecule of a sample material between diamagnetic and paramagnetic states, the sample material is placed on a sample electrode while a static uniform magnetic field of a determined strength is induced through it; a hyperfine ESR detector is used to measure an electrical tunneling current passing through the sample electrode in response to each cycle of the alternating bias voltage, identify in the electrical tunneling current a plurality of hyperfine ESR signals/peaks, each associated with a respective cycle of the alternating bias voltage, and determine a hyperfine ESR frequency thereof; and a NMR analyzer is used to identify in the plurality of hyperfine ESR signals/peaks at least one single spin NMR precession signal/peak based on changes in the plurality of hyperfine ESR signals/peaks.

The detector comprises in some embodiments a tuneable magnetic field applicator configured to induce the uniform magnetic field through the sample electrode. The detector can be configured to adjust the uniform magnetic field for detection of at least one distinguishably strong hyperfine ESR signal/peak by the ESR detector. The detector can be configured to set a strength of the magnetic field induced through the sample by the tuneable magnetic field applicator such that a ratio of the hyperfine ESR frequency detected by the ESR detector and a frequency of the alternating bias voltage substantially equals a positive whole (integer) number. Alternatively, the detector can be configured to set the time interval of the cycles of the alternating bias voltage generated by the pulse generator such that a ratio of the hyperfine ESR frequency detected by the ESR detector and a frequency of the alternating bias voltage substantially equals a positive whole (integer) number.

In some embodiments a band-pass filter is used to extract from the electrical tunneling current a band-pass signal. The ESR detector can be configured to identify in the band-pass signal the plurality of hyperfine ESR signals/peaks. The detector can be configured to tune the band-pass filter to a frequency band determined based on the hyperfine ESR frequency of at least one of the plurality of hyperfine ESR signals/peaks identified in the electrical tunneling current.

The detector comprises in some embodiments at least one of the following: a peak detector configured to detect the at least one hyperfine ESR signal/peak and determine a hyperfine ESR frequency thereof; a spectral decomposition unit configured to provide a spectral representation of the measured tunneling current for the identification of the plurality of hyperfine ESR signals/peaks and their respective hyperfine ESR frequencies; a demodulator configured to demodulate the tunneling current using the hyperfine ESR frequency determined by the ESR detector for at least one of the plurality of hyperfine ESR signals/peaks and generate a demodulated signal thereof; a peak detector configured to detect at least one single spin NMR precession signal/peak in the demodulated signal from the demodulator; an identification module configured to identify a chemical element for the examined atom based on a frequency of the identified at least one single spin NMR precession signal/peak; a composite image generator configured to concurrently receive at least one pixel of an atomic level image of the sample and combine it with respective data associated with the identified at least one single spin NMR precession signal/peak for generating a composite image of atomic level and NMR precession data/signals; one or more RF coils configured to apply electromagnetic irradiation to the examined sample; a pulse width modulation controller configured for adjusting time intervals of low and high state outputs of the alternating bias voltage generated by the pulse generator; a temperature control unit configured to adjust a temperature of the sample for improving detection by the ESR detector and/or the NMR analyzer; and/or a pressure control unit configured to adjust pressure conditions in a volume containing the sample for improving detection by the ESR detector and/or the NMR analyzer.

Optionally, but in some embodiments preferably, the tunneling tip is part of a scanning tunneling microscope (STM).

The detector comprises in some embodiments a tuneable magnetic field applicator and a control unit configured to operate the pulse generator, the tuneable magnetic field applicator, and the ESR detector, to carry out an initialization procedure for scanning a predetermined range of magnetic field strengths induced by the tuneable magnetic field applicator through the sample material while applying the alternating bias voltage to the tunneling tip to identify by the ESR detector at least one hyperfine ESR peak/signal and determine its hyperfine ESR frequency. The control unit can be configured to tune a frequency of the pulse generator such that a ratio of the determined hyperfine ESR frequency and the tuned frequency of the pulse generator substantially equals a whole positive number.

The detector may comprise a magnetic field applicator and a control unit configured to operate the pulse generator, the magnetic field applicator, and the ESR detector, to carry out an initialization procedure for scanning a predetermined range of frequencies of the alternating bias voltage applied by the pulse generator to the tunneling tip while a predetermined magnetic field is induced by the magnetic field applicator through the sample material to identify by the ESR detector at least one hyperfine ESR signal/peak and determine its hyperfine ESR frequency.

The control unit is configured in some embodiments to tune the NMR analyzer to identify the plurality of hyperfine ESR signals/peaks within a frequency range defined based on the hyperfine ESR frequency of the identified at least one hyperfine ESR signal/peak. The control unit may be further configured to control operation of the detector and of an STM for simultaneously generating by the STM a pixel of an atomic level image of the atom or molecule of the sample material placed on the sample electrode and its respective at least one single spin NMR precession signal/peak.

Another aspect of the present application is directed to a single spin nucleus resonance (NMR) measurement system. The system comprises a sample electrode configured to hold sample material thereon at a determined reference voltage level, a tunneling tip configured for adjustable placement in close proximity to the sample electrode and effect an electrical tunneling current therethrough, a pulse generator configured to apply an alternating bias voltage to the tunneling tip in a frequency at least greater than an NMR frequency range and smaller than a hyperfine ESR frequency range for alternatingly changing at least one atom or molecule of the sample material between diamagnetic and paramagnetic states, a magnetic field applicator configured to induce a magnetic field of a determined strength through the at least one atom or molecule of the sample, a hyperfine ESR detector configured to identify in the electrical tunneling current a plurality of hyperfine ESR signals/peaks and determine a hyperfine ESR frequency thereof, and a NMR analyzer configured to identify at least one single spin NMR precession signal/peak based on changes in the plurality of hyperfine ESR signals/peaks.

The system comprises in some embodiments a control unit configured to carry out an initialization procedure for scanning a predetermined range of magnetic field strengths induced by the tuneable magnetic field applicator through the sample material while applying the alternating bias voltage to the tunneling tip to identify by the ESR detector at least one hyperfine ESR peak/signal and determine its hyperfine ESR frequency. Optionally, the control unit is configured to tune a frequency of the pulse generator such that a ratio of the determined hyperfine ESR frequency and the tuned frequency of the pulse generator substantially equals a whole positive number.

The system comprising the control unit can be configured to carry out an initialization procedure for scanning a predetermined range of frequencies of the alternating bias voltage applied by the pulse generator to the tunneling tip while a predetermined magnetic field is induced by the magnetic field applicator through the sample material to identify by the ESR detector at least one hyperfine ESR signal/peak and determine its hyperfine ESR frequency.

The control unit can be configured to tune the NMR analyzer to identify the plurality of hyperfine ESR signals/peaks within a frequency range defined based on the hyperfine ESR frequency of the identified at least one hyperfine ESR signal/peak. In possible embodiments the control unit is configured to control operation of the detector and of an STM for simultaneously generating by the STM a pixel of an atomic level image of the atom or molecule of the sample material placed on the sample electrode and identifying its at least one single spin NMR precession signal/peak.

Another aspect of the present application is directed to a single spin nucleus resonance (NMR) measurement method. The method comprising inducing a static uniform magnetic field of a determined strength through a sample material placed on a sample electrode, applying an alternating bias voltage to a tunneling tip in a frequency at least greater than an NMR frequency range and smaller than a hyperfine electron spin resonance (ESR) frequency range for alternatingly changing within each cycle of the alternating bias voltage at least one atom or molecule of a sample material between diamagnetic and paramagnetic states, measuring an electrical tunneling current passing through the sample electrode in response to each cycle of said alternating bias voltage, identifying in the electrical tunneling current a plurality of hyperfine ESR signals/peaks, each associated with a respective cycle of the alternating bias voltage, and optionally determining a hyperfine ESR frequency thereof, and identifying at least one single spin NMR precession signal/peak based on changes in the plurality of hyperfine ESR signals/peaks.

The method comprises in some embodiments at least one of the following: tuning a strength of the magnetic field induced through the sample such that a ratio of the hyperfine ESR frequency detected by the ESR detector and a frequency of the alternating bias voltage substantially equals a positive whole number; tuning time interval of cycles of the alternating bias voltage such that a ratio of the hyperfine ESR frequency detected by the ESR detector and a frequency of the alternating bias voltage substantially equals a positive whole number; extracting from the electrical tunneling current a band-pass signal and identifying the plurality of hyperfine ESR signals/peaks in said band-pass signal; tuning the extraction of the band-pass signal to a frequency band determined based on the hyperfine ESR frequency of at least one of the plurality of hyperfine ESR signals/peaks; performing spectral decomposition to the measured tunneling current for the identifying of the plurality of hyperfine ESR signals/peaks and their respective hyperfine ESR frequencies; demodulating the tunneling current using the hyperfine ESR frequency determined for at least one of the plurality of hyperfine ESR signals/peaks and generating a demodulated signal thereof; detecting at least one single spin NMR precession signal/peak in the demodulated signal; identifying a chemical element for the examined atom based on a frequency of the identified at least one single spin NMR precession signal/peak; generating a composite image comprising at least one pixel of an atomic level image of the sample and respective data indicative of the identified at least one single spin NMR precession signal/peak; applying electromagnetic irradiation to the examined sample; adjusting time intervals of low and high state outputs of the alternating bias voltage generated by the pulse generator; adjusting a temperature of the sample for improved identification of the hyperfine ESR signals/peaks; and/or adjusting pressure conditions in a volume containing the sample for improved identification of the hyperfine ESR signals/peaks.

The method can include an initialization procedure for scanning a predetermined range of magnetic field strengths induced through the sample material while applying the alternating bias voltage to the tunneling tip and identifying at least one hyperfine ESR peak/signal and determining its hyperfine ESR frequency. Optionally, the method comprises tuning a frequency of the alternating bias voltage such that a ratio of the determined hyperfine ESR frequency and the tuned frequency of the alternating bias voltage substantially equals a whole positive number.

The method may comprise an initialization procedure for scanning a predetermined range of frequencies of the alternating bias voltage applied to the tunneling tip while applying a predetermined magnetic field through the sample material and identifying at least one hyperfine ESR signal/peak and determining its hyperfine ESR frequency.

In some embodiments the method comprises identifying the plurality of hyperfine ESR signals/peaks within a frequency range defined based on the hyperfine ESR frequency of the identified at least one hyperfine ESR signal/peak.

In yet another aspect the present application is directed to a composite image comprising at least one pixel of an atomic level image of a sample and data indicative of single spin NMR precession signal/peak associated with the at least one pixel. The single spin NMR precession signal/peak can be identified utilizing the detectors, systems and/or methods, according to any of the embodiments disclosed hereinabove or hereinbelow.

### BRIEF DESCRIPTION OF THE DRAWINGS

In order to understand the invention and to see how it may be carried out in practice, embodiments will now be described, by way of non-limiting example only, with reference to the accompanying drawings. Features shown in the drawings are meant to be illustrative of only some embodiments of the invention, unless otherwise implicitly indicated. In the drawings like reference numerals are used to indicate corresponding parts, and in which:

FIGS. 1A to 1C schematically illustrate a single spin NMR precession signal detector and principles of its operation according to some possible embodiments, wherein FIG. 1A shows the single spin NMR detector and FIGS. 1B and 1C demonstrate time dependent (in the nuclear Larmor frequency) polarizations of the electron spin due to the ionization of the atom/molecule examined by the single spin NMR detector;

FIGS. 2A to 2D schematically illustrate single spin NMR signals measurement techniques and processes according to some possible embodiments, wherein FIG. 2A shows a single spin NMR spectrum measurement system, FIG. 2B shows a single spin NMR spectrum measurement process utilizing a magnetic field sweep/scan tuning stage e.g., usable when an unknown atom/molecule is examined, FIG. 2C shows a single spin NMR spectrum measurement process based on a tuning stage for sweep/scan of a frequency of the alternating bias voltage, and FIG. 2D shows a modified single spin NMR spectrum measurement system;

FIGS. 3A to 3C schematically illustrate another single spin NMR signals measurement technique, process and imaging, according to some possible embodiments, wherein FIG. 3A shows a system utilizing various circuitries for the single spin NMR spectrum measurement, FIG. 3B shows a respective single spin NMR spectrum measurement process based on a magnetic field sweep/scan, and FIG. 3C shows a composite image comprising imagery data of the measured single spin NMR precession signals;

FIGS. 4A and 4B show atomic microscopy imagery results, wherein FIG. 4A shows atomic structure of TEMPO radical molecule and an STM image thereof and FIG. 4B shows atomic structure of toluene and an STM image thereof;

FIGS. 5A and 5B respectively show STM images of graphene without and with ⁶⁰C molecules;

FIGS. 6A to 6D show ionization of ⁶⁰C molecules using several bias voltage levels;

FIGS. 7A and 7B show ESR-STM spectrum of a single TEMPO molecule acquired at 90 seconds and 0.1 second time intervals, respectively;

FIGS. 8A and 8B show single spin ¹⁴N NMR peaks of the TEMPO molecule observed for different frequency analysis of the central hyperfine peak;

FIGS. 9A to 9C show single spin NMR spectra obtained for ¹H in toluene, wherein FIG. 9A shows ¹H in toluene gyromagnetic ratio, FIG. 9B shows high resolution single spin NMR spectra enabling identification of toluene in the single molecule level, and FIG. 9C shows a comparable macroscopic spectrum of the same; and

FIG. 10 shows high resolution spectrum of toluene with smaller chemical shift between the aromatic and aliphatic hydrogen peaks.

### DETAILED DESCRIPTION OF EMBODIMENTS

One or more specific and/or alternative embodiments will be described below with reference to the drawings, which are to be considered in all aspects as illustrative only and not restrictive in any manner. It shall be apparent to one skilled in the art that these embodiments may be practiced without such specific details. In an effort to provide a concise description of these embodiments, not all features or details of an actual implementation are described at length in the specification. Elements illustrated in the drawings are not necessarily to scale, or in correct proportional relationships, which are not critical. Emphasis instead being placed upon clearly illustrating the principles of the invention such that persons skilled in the art will be able to make and use the single spin NMR precession signal measurements and setups, once they understand the principles of the subject matter disclosed herein. This invention may be provided in other specific forms and embodiments without departing from the essential characteristics described herein.

The present application according to some embodiments thereof provides techniques and setups for measuring NMR spin precession signals of a single atom examined by a tunneling tip. In general, the measurements are carried out by applying an alternating bias voltage to a tunneling tip located few Angstroms [Å] from an examined atom/molecule of a sample placed on a sample electrode. The sample electrode is maintained in a desired electrical voltage level (e.g., “0”/zero Volt), and under application of a relatively low constant/static magnetic field (e.g., up to few hundred Gauss). The alternating bias voltage applied to the tunneling tip causes within each cycle thereof (also referred to herein as ESR cycle) temporary ionization of the examined atom/molecule and passage of a corresponding electrical current therethrough (referred to as tunneling current herein). The tunneling current measured during each ESR cycle is processed and analysed to detect and record ESR hyperfine peak signals occurring therein as a function of time.

Due to the anisotropy of the hyperfine coupling together with the relatively low external magnetic field, the effective magnetic field in the paramagnetic and the diamagnetic states of the examined atom/molecule are not in the same direction. It is now understood that the amplitude of the single ESR hyperfine peak detected in each ESR cycle is modulated in time, at the Larmor frequency of the nuclear of the examined atom. Indeed, the observed spectrum shows a peak in the Larmor frequency of the examined atoms (e.g., as demonstrated hereinbelow for ¹⁴N and ¹H nuclei). Some of the results obtained are showing also a peak at half of the Larmor frequency of the examined atom.

The embodiments and examples provided herein demonstrate randomity of the detected position, simplicity of the disclosed detection technique, and feasibility of substantially fast (e.g., within 1 second in some embodiments) single NMR spins detection, utilizing relatively inexpensive equipment. Indeed, the results show that the single spin NMR techniques disclosed herein have the advantage that the particular atom/molecule examined by the tunneling tip can provide an NMR spectrum, and that the surface of the examined sample can be concurrently (or shortly after, or shortly before, the single spin NMR signal/peak detection) imaged with atomic level resolution. In addition, the disclosed techniques and setups enable to observe high resolution spectrum of a single molecule, which is similar to the macroscopic spectrum on the same molecules.

The spectral resolution of the single spin NMR detection disclosed herein is improved in some embodiments by controllably adjusting the ratio between the external magnetic field applied and the anisotropic hyperfine interaction, which must be significant, and/or by adjusting the ratio between the NMR precession (diamagnetic) time period and the ESR (paramagnetic) time period.

In some embodiments the single spin NMR signal measurement setup of embodiments disclosed herein is combined in an STM system configured to concurrently acquire atomic level imaging data/signals and single spin NMR precession data/signals from each atom/molecule examined by the tunneling tip. The results presented hereinbelow show that a measurement of about 1 (one) second is sufficient to acquire NMR spectrum for each pixel in the STM atomic level image, which thus adds to the STM system the significant ability not only to image/see the atom (or molecule) examined by the tunneling tip, but also to identify its chemical element(s) and/or environment.

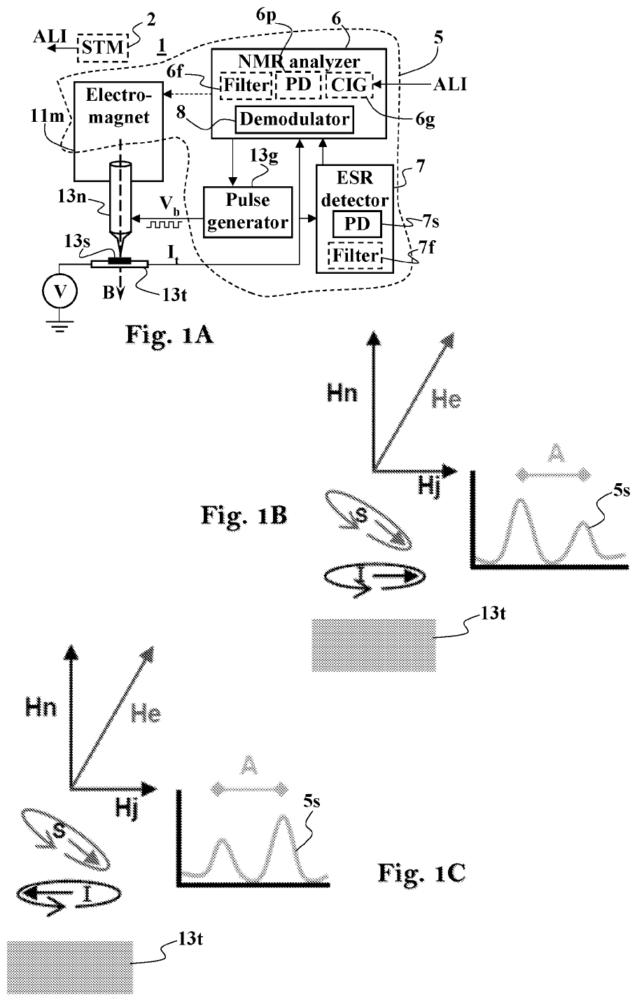

It is now understood that when there is a molecular hyperfine coupling between an electron and a nucleus, the measured ESR precession signals can be used as a detector to the NMR precession [8]. And that when the polarization of the nuclear levels is modified, the intensity of the hyperfine peaks is modified as well [9]. Thus, as a result of ionization, when the electron (in the paramagnetic phase) and the nucleus (in the diamagnetic phase) do not precess around a magnetic field with the same direction (e.g., as exemplified in FIGS. 1B and 1C), the polarization of the nuclear state when the hyperfine ESR signal/peak is detected is modified. When the anisotropy of the hyperfine coupling is in the same order of magnitude as the external magnetic field, the directions of the effective field in the diamagnetic state and the paramagnetic state are naturally different.

For an overview of several example features, process stages, and principles of the invention, the single spin NMR precession signal measurement examples illustrated schematically and diagrammatically in the figures are intended for use with a tunneling tip, such as used in STM systems. These setups/techniques are shown as one example implementation that demonstrates a number of features, processes, and principles used for the single spin NMR precession signal measurement, but they are also useful for other applications and can be made in different variations e.g., using other ionization techniques/setups. Therefore, this description will proceed with reference to the shown examples, but with the understanding that the invention recited in the claims below can also be implemented in myriad other ways (e.g., using RF pulses to excite the nucleus), once the principles are understood from the descriptions, explanations, and drawings herein. All such variations, as well as any other modifications apparent to one of ordinary skill in the art and useful for NMR precession signals measurement may be suitably employed and are intended to fall within the scope of this disclosure.

It is noted that the single spin NMR techniques/setups disclosed herein, and demonstrated in the examples hereinbelow, were shown to work at room temperature, utilizing relatively low magnetic fields (up to few hundreds Gauss) and a normal/regular tunneling (e.g., STM) tip (i.e., without tip magnetizations), and without application of external electromagnetic RF irradiation, and that they can be generalized for all atoms and molecules.

FIG. 1A schematically illustrates a single spin NMR detector 5 according to some possible embodiments, and an NMR signal measurement system 1 comprising the single spin NMR detector 5. The single spin NMR detector 5 comprises a pulse generator 13g configured to apply an alternating bias voltage V_{b} to a tunneling tip 13n located in close proximity to a sample material 13s examined on a sample electrode 13t, while a fixed/constant magnetic field B is induced through the sample, a hyperfine ESR detector 7 configured to measure hyperfine ESR signals/peaks in a tunneling current Iₜ passing through the sample electrode 13t in response to each bias voltage cycle/pulse V_{b} applied to the tunneling tip 13n, and an NMR analyzer 6 configured to determine at least one single spin NMR precession signal/peak based on changes in a plurality of hyperfine ESR signals/peaks detected in the tunneling current Iₜ. The single spin NMR detector 5 comprises in some embodiments a tuneable magnetic field applicator 11m.

The ESR detector 7 comprises in some embodiments a peak (e.g., envelope) detector (PD) 7s configured to detect hyperfine ESR signals/peaks in the measured tunneling current Iₜ for each ESR/ionization cycle/pulse of the alternating bias voltage V_{b}. Optionally, one or more filters 7f are used in the ESR detector 7 to remove noise from the measured tunneling current Iₜ, such as introduced by the alternating bias voltage V_{b}. Optionally, but in some embodiments preferably, the hyperfine ESR detector 7 is implemented by a spectrum analyzer configured to detect the hyperfine ESR signal/peak modulated by the NMR Larmor frequency of the inspected atom/molecule.

The NMR analyzer 6 comprises in some embodiments a demodulator 8 configured to demodulate the tunneling current Iₜ using a hyperfine ESR frequency of at least one hyperfine ESR signal/peak detected by the ESR detector 7. The NMR analyzer 6 can be configured to perform a scan of the strength of the externally applied magnetic field B, or of the frequency of the alternating bias voltage V_{b}, to determine NMR measurement conditions wherein a ratio between the hyperfine ESR frequency used for the NMR detection and the frequency of the alternating bias voltage is substantially an integer. Optionally, but in some embodiments preferably, the NMR analyzer 6 is implemented by a rapid scope configured to records the hyperfine ESR signals/peaks and for calculation of the NMR spectrum e.g., by spectral analysis, such Fourier transform or a digital spectrum analysis, tools using a computer to eliminate only the modulating frequency (of the NMR).

The configuration depicted in FIG. 1A is however not limited for the initial stage of finding the optimal (or an observable) ESR hyperfine peak frequency. In possible embodiments the NMR analyzer 6 is further configured to process a plurality of hyperfine ESR signals/peaks detected by the ESR detector 7 for a respective plurality of ionization/ESR cycles/pulses and determine at least one single spin NMR precession signal/peak therefrom based on changes in the plurality of hyperfine ESR signals/peaks. Accordingly, the ESR hyperfine peaks measurements can be adjusted for each pixel e.g., by finding the hyperfine frequency for which the greatest hyperfine ESR peak is detected, and which can be carried out automatically by the system. The NMR spectrum can be detected from the NMR induced modulated hyperfine peak.

Optionally, the NMR analyzer 6 comprises a peak (e.g., envelope) detector (PD) 6p configured to detect the single spin NMR precession signals/peaks frequency in the measured tunnelling current Iₜ. In another optional configuration the ESR detector 6 comprises one or more filters 6f configured to filter the tunneling current Iₜ before it is demodulated by the demodulator 8 (and/or by the peak/envelope detector 6p). The one or more filters 6f can be configured to remove noise from the tunneling current Iₜ (e.g., such as introduced by the alternating bias voltage V_{b} cycles/pulses) and/or extract therefrom a band pass signal having a band pass frequency range defined based on a hyperfine frequency of at least one hyperfine ESR signal/peak detected by the ESR detector 7.

Optionally, the NMR analyzer is configured to carry our demodulation utilizing a scope, and the signals/data thereby produced is transferred to a computer configured to calculate the low frequency NMR spectrum e.g., which by Fourier transform or digital spectrum analyser.

In possible embodiments the tunneling tip 13n is part of an STM system 2 configured to generate an atomic level image (ALI) simultaneous with the single spin NMR precession signal/peak measurements carried out by the NMR detector 5. In such embodiment the NMR analyzer 6 can further comprise a composite image generator (CIG) 6g configured to combine each atomic level pixel of the ALI with a respective single spin NMR precession signal/peak (and/or other related spectroscopic properties) detected by the NMR analyzer 6. This way a composite image comprising both the atomic level and single spin NMR precession imagery data/signals can be generated within a single scan of the sample 13s by the tunneling tip 13n.

FIGS. 1B and 1C schematically illustrate the precession of the electron (S) in the quasi-static orientation of the nucleus (I), as measured in embodiments hereof. As seen, the projection of the precession of the nucleus (I) in the direction of the magnetic field He experienced by the electron is positive in the first state exemplified in FIG. 1B. As exemplified in FIG. 1C, the projection of the precession of the nucleus on He is switched into the negative direction when the nucleus spin is polarized in the quantization axes of the electron due to the ionization of the atom/molecule and the addition to the hyperfine field by the externally applied magnetic field, and the change in the direction of the total field. The spectra 5s shown (in green) in FIGS. 1B and 1C are the expected hyperfine spectra due to the differences in the polarization of the nucleus, where A is the hyperfine splitting.

Thus, the polarization of the nuclear state and the intensity of the hyperfine peaks (FIGS. 1B and 1C) are dependent on the position of the nucleus. In embodiments disclosed herein the ionization cycles/pulses of the examined atom/molecule is carried out within relatively short time intervals (e.g., 10 to 100 nanoseconds, when the ratio between the hyperfine ESR frequency and the alternating bias voltage modulation frequency is an integer), such that the nucleus of the examined atom/molecule is quasi-static within the time intervals in which the electron spin precession is measured via the detected hyperfine ESR precession signals/peaks. Initially, when the examined atom/molecule is in the paramagnetic state, the hyperfine peaks detected by the ESR signal/peak are equal in size. When the examined atom/molecule transfers into the diamagnetic states due to the ionization, the precession of the nucleus around Hn changes the nuclear polarization (in the frame of He), which appears as unequal amplitude of the hyperfine peaks detected by the ESR signal/peak.

At the time wherein the examined atom/molecule transfers back to the paramagnetic state, the nucleus precess around a field with a different direction (He), which is much larger than the external field applied by the system B. However, the accumulated longitudinal polarization of the nucleus is preserved due to the slow spin-lattice (longitudinal) magnetization relaxation time (T1) of the nuclear. Therefore, when the electron is removed from the examined atom/molecule, the nuclear polarization is projected back on the original direction (Hn), and it is returning to the position it was before the electron was introduced into the examined atom/molecule. This happens when the ratio between the hyperfine ESR frequency and the frequency of the alternating bias voltage modulation frequency is an integer. This explains how the nuclear precession and the amplitude modulation of the hyperfine peaks are continuous also with the ionization cycles/pulses.

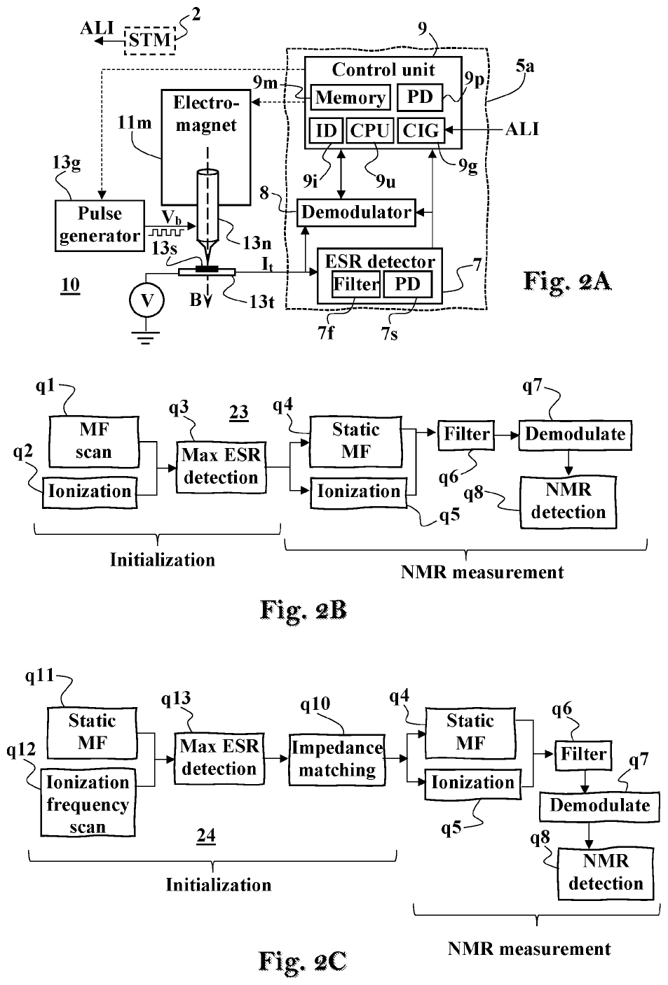

FIG. 2A schematically illustrates a single spin NMR measurement system 10 according to some possible embodiments. The system 10 comprises a sample electrode 13t configured to hold examined sample material 13s thereon at a defined electric voltage level (e.g., “0”/zero Volt), a tunneling tip 13n placed in very close proximity to the sample electrode 13t (e.g., few Angstroms), a pulse generator 13g electrically coupled to the tunneling tip 13n for applying a periodically alternating bias voltage V_{b} thereto, an electromagnet 11m configured to induce a substantially uniform magnetic field B through the examined atom/molecule of the sample 13s, and a single spin NMR measurement unit 5a. The single spin NMR measurement unit 5a is configured to operate the pulse generator 13g and electromagnet 11m, process the tunneling currents Iₜ passing through the sample electrode 13t, and determine therefrom single spin NMR precession signals.

The pulse generator 13g is configured in some embodiments to generate a continuous rectangular electrical voltage pulse signal V_{b} applied to the tunneling tip 13n. The frequency F_{b} of the alternating bias voltage V_{b} can generally be in the range of 100 kHz to 100 MHZ, and its voltage levels in the low-state output can be about 0 to 0.5 Volt, optionally about 0.2 Volt. and in the high-state output about 1 to 4 Volt, optionally about 3.7 Volt (i.e., the ionization voltage must be larger than the energy of the orbital that is receiving the ionizing electron). The pulse generator 13g is configured in some (or all) embodiments to generate the alternating bias voltage having a frequency that is larger than the NMR spin precession frequency and much smaller than the ESR spin precession frequency e.g., for hydrogen atom the frequency of the alternating bias voltage should be large than 3 MHZ and smaller than 20 MHZ. The electromagnet 11m is configured in some embodiments to generate a substantially uniform magnetic field B through the examined atom/molecule between 0 to few hundred Gauss e.g., 0 to 400 Gauss, optionally between 0 to 400 (or 600) Gauss i.e., the externally applied magnetic field B should be small enough such that the perpendicular hyperfine field is not negligible.

The single spin NMR measurement setup 5a comprises an ESR detector 7, a demodulator 8, and a control unit 9. The ESR detector 7 is configured to detect and measure hyperfine ESR signals/peaks in the tunneling current Iₜ passing through the sample electrode 13t due to each bias voltage cycle/pulse of the alternating bias voltage signal V_{b} applied to the tunneling tip 13n, and determine a hyperfine frequency for each of the ESR hyperfine signals/peaks thereby detected. The demodulator 8 is configured to tune to a frequency of at least one of the hyperfine ESR peaks detected by the ESR detector 7 for demodulating the tunneling current Iₜ.

In some embodiments the ESR detector 7 comprises a peak detector (PD) 7s configured to detect (maximal/minimal) ESR peaks/signals in the measured tunneling current Iₜ. The peak detector may utilize, for example, circuitry/algorithm for simple (highest) spike detection, and/or detection of signal deviations from a determined signal baseline or moving average. Optionally, one or more filters 7f as used in the ESR detector 7 to remove noise from the tunneling current Iₜ before it is processed by the peak detector 7s, and/or to generate a band-pass signal for extracting portions of the tunnelling current containing the ESR hyperfine peak/signal e.g., with suitable detection bandwidth of few MHz to few tenths of MHZ, optionally about 100 to 200 MHZ. The ESR detector 7 can be configured to tune the demodulator 8 to a frequency of at least one of the hyperfine ESR peaks detected by its PD module 7s. Alternatively, the control unit 9 is configured to tune the demodulator 8 to a frequency of at least one of the hyperfine ESR peaks detected by the ESR detector 7, or by its one or more processors 9u based on the input signals/data received from the ESR detector 7 and/or the demodulator 8.

The control unit 9 comprises one or more processing units 9u and memories 9m configured and operable to process and record amplitude and frequency of at least some of the hyperfine ESR peaks as received from the ESR detector 7, and/or process and analyse the demodulated signal generated by the demodulator 8, to measure therein at least one single spin NMR precession signal indicative of the Larmor frequency of the nucleus of the examined atom/molecule. For this purpose, the control unit 9 comprises in some embodiments a peak detector (PD) 9p configured to process and analyse the signals received from the demodulator 8 and/or from the ESR detector 7. Optionally, but in some embodiments preferably, the control unit 9 comprises an identification (ID) module 9i configured and operable to identify chemical element(s) of the examined atom/molecule based on the single spin NMR precession signals detected by the PD 9p (e.g., based on a frequency of at least one detected single spin NMR peak being indicative of its Larmor frequency).

Optionally, but in some embodiments preferably, the tunneling tip 13n is part of a STM system 2 configured to generate an atomic level image (ALI) of the sample 13s, simultaneous with the single spin NMR precession signals measurements carried out by the system 10. In possible embodiments the control unit 9 comprises a composite image generator (CIG) 9g configured and operable to receive data/signals of an ALI (e.g., generated by an electronic microscope, such as STM 2) of at least some portion of the sample 13s, and match to each atom/molecule in the received ALI at least one corresponding single spin NMR precession/peak signal/frequency detected by the PD 9p.

The single spin NMR precession signal measurement technique is based on measurement of the changes over time in hyperfine ESR peaks detected in the tunneling current Iₜ in response to the alternating bias voltage V_{b} cycles/pulses applied to the tunneling tip 13n under application of a uniform external magnetic field B induced through the sample 13s by the electromagnet 11m. The external magnetic field B induced through the sample 13s causes changes in the frequency corresponding to the hyperfine splitting of the energy levels of the atom/molecule of the sample examined by the tunneling tip 13n, and the alternating bias voltage V_{b} is configured to cause sequential ionization of the atom/molecule examined by the tunneling tip 13n, thereby sequentially changing the atom/molecule between paramagnetic and diamagnetic states. During the sequential ionization of the examined atom/molecule the intensities of the hyperfine ESR peaks detected in the tunneling current Iₜ is modulated responsive to the NMR spin excitations of the nucleus of the examined atom/molecule.

FIG. 2B is a flowchart schematically illustrating a single NMR precession signal measurement process 23 according to some possible embodiments. The process 23 generally includes an initialization stage (steps q1 to q3), and a single spin NMR measurement stage (steps q4 to q8), which in some embodiments are performed for each pixel of the ALI. The process 23 starts in steps q1 and q2 configured to induce through the sample 13s a gradually changing magnetic field B scan by the electromagnet 11m, and simultaneously apply the alternating bias/ionization voltage V_{b} having a predetermine frequency F_{b} to the tunneling tip 13n. The control unit 9 can be configured to generate respective control signals for the pulse generator 13g to generate the alternating bias voltage V_{b} in a predetermined frequency, and for the electromagnet 11m to generate a slowly varying magnetic field B. During the execution of steps q1 and q2 the tunneling current Iₜ is measured for each bias voltage V_{b} cycle/pulse and analysed in step q3 to determine the following:
(1) a maximal (or minimal) ESR peak measured by the ESR detector 7 in the measured tunneling current Iₜ i.e., ESR maximum or minimum of greatest magnitude (i.e., extremum) observed within the magnetic field scan;
(2) the respective hyperfine ESR frequency Fₕ of the determined ESR peak extremum (i.e., the optimal hyperfine frequency); and
(3) the respective magnetic field Bₘ applied by the electromagnet 11m when the ESR peak extremum occurred in the measured tunneling current Iₜ.

Alternatively, the control unit 9 can be configured to detect at least one strong/distinguishable ESR peak measured by the ESR detector 7 and determine its respective hyperfine frequency (i.e., an observable frequency) for use in the NMR measurement stage. The hyperfine ESR (optimal or observable) frequency Fₕ determined in step q3 is thereafter used for tuning the single spin NMR measurement stage. The rate of change of the magnetic field induced through sample during execution of initializing steps q1, q2 and q3, can generally be in the range of 1 to 5 Gauss/second, optionally about 2 Gauss/second, and the entire time interval of these initializing steps can generally be about 30 to 400 seconds, optionally 50 to 150 seconds, or about 75 seconds. It is important to note that this the ESR spectrum can be accurately revealed, which can provide important complementary information on the examined molecule/atom.

In order to guarantee effective single spin NMR precession signals detection in the tunneling current Iₜ the ratio of the hyperfine ESR (optimal or observable) frequency Fₕ of the hyperfine ESR peak signals to be used for the single spin NMR precession signal measurement stage and the frequency F_{b} of the alternating bias voltage V_{b} should substantially equal a positive integer number i.e., Fₕ/F_{b}=k, wherein k>0 is an integer number. Optionally, but in some embodiments preferably, the ratio Fₕ/F_{b} substantially equals a positive integer number k in the range of 1≤k<80.

Steps q4 and q5 of the single spin NMR precession signal measurement stage are then performed to continuously induce a constant/static magnetic field Bₘ (as determined in step q3 for the hyperfine ESR peak extremum, or observability condition) through the sample 13s, and simultaneously apply the alternating bias/ionization voltage V_{b} having the F_{b} frequency used in the initializing ionization step q2 i.e., a substantially same alternating bias voltage V_{b} is applied in steps q2 and q5. The tunneling current Iₜ is measured during execution of steps q4 and q5 for each cycle/pulse of the bias/ionization voltage V_{b} and optionally filtered in step q6 to remove noise introduced thereinto by the periodic alternating bias/ionization voltage V_{b}. The demodulation step q7 is also tuned to the hyperfine ESR (optimal or observable) frequency Fₕ of the hyperfine ESR peak extremum (or complying to the observability condition) determined in step q3 to extract from the tunneling current Iₜ measured in steps q4 and q5 the single spin NMR precession signals. In step q8 the single spin NMR precession signals obtained after the demodulation of step q7 are processed and analysed to detect single spin NMR (maximum and/or minimum) extremum peak(s), and optionally also to determine chemical element(s) of the examined atom/molecule. The time interval of the single spin NMR precession signal measurement (cycle) stage q4 to q8 can generally be about 0.75 to 1.25 seconds, optionally in the order of magnitude of the relaxation time of the nucleus i.e., about 1 second.

FIG. 2C is a flowchart schematically illustrating a single NMR precession signal measurement process 24 according to other possible embodiments. The process 24 of FIG. 2C differs from the process 23 of FIG. 2B in that it is configured to scan the frequency F_{b} of the alternating bias/ionization voltage V_{b} (e.g., between 100 kHz to 700 MHZ, but in some embodiments should be larger than the NMR frequency (>1 MHZ) range, and smaller than the ESR frequency range (<630 MHZ)) e.g., of hydrogen at 230 Gauss, instead of scanning the magnetic field B induced through the sample, and thus requires the additional impedance matching step q10. In some embodiments the frequency F_{b} of the alternating bias voltage V_{b} is in the range of 2 MHZ 31 MHz, optionally 3≤F_{b}≤30 MHz. Accordingly, the initialization stage (steps q11 to q10) of the process 24 of FIG. 2C includes the additional impedance matching step q10.

The process 24 starts in steps q11 and q12 configured to induce through the sample 13s a predetermined static/constant magnetic field B (e.g., of few hundred Gauss) by the electromagnet 11m, and simultaneously apply the alternating bias/ionization voltage V_{b} with a gradually changing frequency F_{b} to the tunneling tip 13n. The control unit 9 can be configured to generate respective control signals for the pulse generator 13g to generate the alternating bias voltage V_{b} with the gradually changing frequency F_{b}, and for the electromagnet 11m to generate the static/constant magnetic field B in a predetermined strength. During the execution of steps q11 and q12 the tunneling current Iₜ is measured and analysed in step q13 to determine the following:
(1) hyperfine ESR extremum (or strong/distinguishable) peak(s) measured by the ESR detector 7 in the measured tunneling current Iₜ within the magnetic field scan;
(2) the respective hyperfine (optimal or observable) ESR frequency Fₕ of the determined hyperfine ESR extremum (or strong/distinguishable) peak; and
(3) the respective frequency F_{b} of the alternating bias voltage for which the hyperfine ESR extremum (or strong/distinguishable) peak occurred in the measured tunneling current Iₜ within the magnetic field scan.

The hyperfine ESR frequency Fₕ determined in step q13 is thereafter used for tuning the single spin NMR precession signal measurement stage, and the frequency F_{b} of the alternating bias/ionization voltage determined in step q13 is used in step q10 for impedance matching the single spin NMR signal measurement equipment. As mentioned hereinabove, in order to guaranty efficient single spin NMR precession signals detection in the tunneling current Iₜ the ratio of the hyperfine (optimal or observable) ESR frequency Fₕ of the ESR peak signals to be used for the single spin NMR precession signal measurement stage and the frequency F_{b} of the alternating bias/ionization voltage V_{b} should substantially equal an integer i.e., Fₕ/F_{b}=Integer e.g., within a defined precision. The rate of change of the frequency F_{b} of the alternating bias voltage applied to the sample electrode during execution of the initializing steps q11, q12 and q13, can generally be about F_{b}/100 Hz/second e.g., in the range of 10 to 6000 kHz/second, optionally 20 to 300 kHz/second, or about 30 kHz/second, and the entire time interval of the initializing steps can generally be about 20 to 150 seconds.

Steps q4 and q5 are then performed to continuously induce the predetermined constant/static magnetic field B (same as in step q11) through the sample 13s, and simultaneously apply the alternating bias/ionization voltage V_{b} having the frequency F_{b} determined in step q13. The tunneling current Iₜ is measured during execution of steps q4 and q5 each cycle/pulse of the alternating bias/ionization voltage V_{b}, and optionally filtered in step q6 to remove noise introduced thereinto by the alternating bias voltage V_{b}. The modulation step q7 is similarly tuned to the hyperfine (optimal or observable) ESR frequency Fₕ of the hyperfine ESR extremum (or observable) peak detected in step q13 to extract from the tunneling current Iₜ measured in steps q4 and q5 the single spin NMR precession signals. In step q7 the single spin NMR precession signals obtained after the demodulation of step q7 are processed and analysed to detect single spin NMR extremum peak(s), and optionally also to determine chemical element(s) of the examined atom/molecule. The time interval of the NMR measurement (cycle) steps q4 to q8 in FIG. 2C can be more or less the same time interval as required to carry out these steps in FIG. 2B.

FIG. 2D schematically illustrates a modified single spin NMR signal measurement system 10′ according to some possible embodiments. The system 10′ of FIG. 2D is generally similar to the system 10 of FIG. 2A but utilizes additional/optional components that may be used to improve the single spin NMR precession signals measurements. For example, in some embodiments a pulse-width-modulation (PWD) controller 13w is used in the pulse generator 13g for controllably regulating the T and T′ time intervals of the high-state and low-state outputs of the alternating bias voltage V_{b} thereby generated. The control unit 9 can be accordingly configured to generate control signals for regulating the T and T′ time intervals used by the PWD controller 13w in order to improve quality and/or accuracy of the single spin NMR precession signal measurements. The PWD controller 13w can be similarly used in the single spin NMR measurement systems shown in FIGS. 1A, 2A, and/or 3A.

Additionally or alternatively, as also seen in FIG. 2D, in some possible embodiments the sample electrode 13t and at least a portion of the tunneling tip 13n are enclosed inside a measurement chamber 13b configured to controllably set desired measurement conditions for the single spin NMR signal acquisition. For example, a temperature control unit 13e can be used for setting the temperature (e.g., using controllable heater/cooler device) inside the measurement chamber 13b to a desired temperature to improve the single spin NMR signals measurements e.g., based on control signals/data received from the control unit 9. As another example, the measurement chamber 13b may additionally or alternatively use a pressure control unit 13r configured to set a desired pressure conditions (e.g., using a controllable pressure/vacuum pump—not shown) thereinside to improve the single spin NMR precession signals measurements e.g., based on control signals/data received from the control unit 9.

Optionally, as also seen in FIG. 2D, the PD 7s of the ESR detector 7 may utilize a spectral decomposition (e.g., fast Fourier transform—FFT) module 7t configured to provide spectral representation of at least a portion of the tunneling current Iₜ, usable for determination of the hyperfine ESR extremum (or observable peaks). Also optionally in some embodiments the control unit 9 comprises a digital signal processing (DSP) module 9d configured to detect (e.g., utilizing peak detection and/or spectral decomposition/FFT modules/algorithms implemented therein—not shown) the single spin NMR precession signals/peaks in the demodulated signals generated by the demodulator 8 and/or in the hyperfine ESR signals/peaks detected by the ESR detector 7.

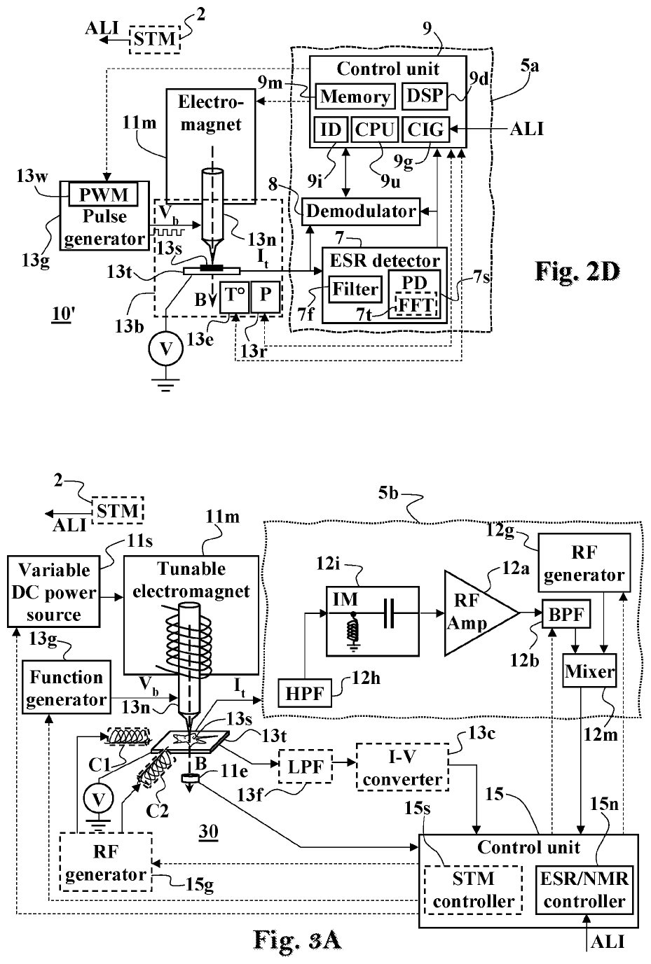

FIG. 3A schematically illustrates a system 30 configured for exciting and measuring NMR spin precession signals in a single atom/molecule of a sample 13s examined by a tunneling tip 13n e.g., of the STM system 2. The system 30 comprises a sample electrode 13t configured to hold the sample 13s thereon, and to maintain at a determined constant voltage level (e.g., “0”/zero Volt), a tuneable electromagnet 11m electrically coupled to a variable power source 11s for inducing a substantially uniform magnetic field B through the examined atom/molecule of the sample 13s, a function generator 13g for applying an alternating (e.g., rectangular wave) bias/ionization voltage V_{b} to the tunneling tip 13n, a single spin NMR precession signal measurement circuitry 5b, and a control unit 15.

The system 30 is configured in some embodiments for detecting single spin NMR precession signals in the tunneling current Iₜ, which are indicative of the Larmor frequency of the nucleus of the examined atom/molecule. This way the atom/molecule examined by the tunneling tip (13n), and/or its chemical environment, can be identified e.g., based on single spin NMR peak(s) detected measured signal. Here, a band pass filter (BPF) 12b and a mixer 12m are used in the measurement circuitry 5b to extract and measure the NMR precession signals from the hyperfine ESR peaks occurring in the tunneling current Iₜ. Optionally, but in some embodiments preferably, the measurement circuitry 5b comprises a high pass filter (HPF) 12h configured to remove noise signals introduced into the tunneling current e.g., by the alternating bias voltage V_{b}. A RF amplifier 12a may be also utilized for amplifying the filtered tunneling current Iₜ. An impedance matching (IM) circuitry 12i can be used for matching the RF amplifier 12a to the frequency F_{b} of the alternating bias voltage V_{b}. it is noted that the impedance matching may be similarly used in the other embodiments shown in FIGS. 1A, 2A and/or 2D.

After passing through the high pass filter (HPF 12h) the measured tunneling current is amplified by the RF amplifier (12a) and then filtered again by the BPF 12b to extract therefrom band pass signal having frequencies within a window centered (e.g., 100 to 200 MHZ) about the hyperfine ESR frequency Fₕ for which the hyperfine extremum (or observable) peak was detected in the initialization step (e.g., as recorded in step s2 of FIG. 3B). The signal from the BPF 12b is then demodulated by the mixer 12m configured to use for the demodulation the signal generated by the RF generator 12g, which is also tuned to the hyperfine ESR (optimal or observable) frequency Fₕ for which the hyperfine extremum (or observable) peak was detected in the initialization step, for generating a low frequency signal of several MHz for analysis by the ESR/NMR controller 15n.

The single spin NMR precession signal measurement technique of system 30 is also based on measurement of the changes over time in the ESR hyperfine peaks detected in the tunneling current Iₜ in response to the alternating bias/ionization voltage V_{b} applied to the tunneling tip 13n under application of the external magnetic field B (e.g., vertically) induced through the sample 13s by the tuneable electromagnet 11m to cause hyperfine splitting changes in the atom/molecule of the sample. Similarly, the alternating bias/ionization voltage V_{b} is configured to cause sequential ionization of the atom/molecule examined by the tunneling tip 13n, and to thereby sequentially change the examined atom between paramagnetic and diamagnetic states.

As in the previous examples, for suitable magnetic field B magnitudes and suitable alternating electric bias/ionization voltages V_{b} applied in short bursts to the tunneling tip 13n the atom/molecule under the tunneling tip 13n is forced into hyperfine ionized states (by gaining or losing an electron) causing electron and nucleus precessions in short time periods in which the nuclei of the atom is quasi-static. The nucleus precession in the diamagnetic states affects the magnetic field experienced by the unpaired electron of the atom precessing in the paramagnetic state, thereby modulating the ESR hyperfine peaks that the system can detect.

FIG. 3B is a flowchart showing a single spin NMR precession signals measurement process 28 according to some possible embodiments. As in the previous examples, the process 28 starts in initialization/tuning stage of steps s1, s2 and s3, used for determining settings for tuning the NMR measurement circuitries for single spin NMR precession signals measurement stage of steps s4 to s7. In step s1 the tunneling current Iₜ passing through the sample electrode 13t is measured and analysed for each cycle/pulse of the alternating bias voltage V_{b} applied by the function generator 13g to the tunneling tip 13n in a predefined modulation frequency (F_{b} in a range of few tenths to few hundred MHz e.g., 15.675 MHZ) to the tunneling tip 13n, and the static uniform magnetic field B is applied by the tuneable electromagnet 11m in gradually varying intensities (e.g., swept between 0 to 400 Gauss, optionally between 250 to 400 or 600 Gauss in accordance with the variable DC power source (11s) driving it.

As in the previous examples, the hyperfine ESR peak(s) may be detected at a single frequency (e.g., 627 MHZ, but it can be any other frequency which is the best in terms of impedance matching). Accordingly, the strength of the externally applied magnetic field B can be changed by the tuneable electromagnet 11m to observe hyperfine ESR peaks at different frequencies e.g., detectable at 627 MHz. As explained hereinabove, in order to guarantee efficient single spin NMR precession signal/peak detection the frequency F_{b} of the alternating bias/ionization voltage V_{b} should be selected such that dividing the (optimal or observable) frequency Fₕ of the detected hyperfine ESR signals/peaks (e.g., 627 MHZ) by the frequency F_{b} of the alternating bias/ionization voltage V_{b} (e.g., 15.675 MHZ) results in a substantially positive integer number (e.g., Fₕ/F_{b}=627/15.675=40) within the defined precision i.e., the residue of the division should be substantially zeroed (0) or negligibly small. Optionally, the frequencies ratio Fₕ/F_{b} is an integer number in the range of 1 to 80.

In step s2 the tunneling current Iₜ is measured for each cycle/pulse of the alternating bias/ionization voltage V_{b} (e.g., using a suitable probe 11e, such as a Hole probe), recorded and analysed, to detect a hyperfine ESR extremum (or observable) peak occurring therein during the magnetic field sweep carried out by the tuneable electromagnet 11m. The corresponding external magnetic field B applied when the extremum (or observable) ESR hyperfine peak is observed in the tunneling current Iₜ, and its respective (optimal or observable) hyperfine frequency Fₕ, are also determined and recorded. In step s3 the DC source 11s is tuned for generation of a stationary/static magnetic field B in the intensity recorded in step s2 (i.e., that corresponds to the detected extremum or observable ESR hyperfine peak), and the band pass filter 12b and the RF generator 12g are tuned to the (optimal or observable) hyperfine ESR frequency Fₕ recorded in step s2 for the maximal/minimal (or observable) ESR peak.

A tunneling current Iₜ measurement is then carried out is step s4 using the external stationary/static magnetic field (B) recorded in step s2 and the same alternating bias/ionization voltage V_{b} having the same frequency F_{b} used in step s1. In step s5 the measured tunneling current Iₜ is filtered by the HPF 12h, amplified by the RF amplifier 12a, and in step s6 the amplified signal is demodulated by the mixer 12m. The demodulated signal produced by the mixer 12m is analysed by the ESR/NMR controller 15n to detect the single spin NMR signal/peak in step s7. The ESR/NMR controller 15n can be equipped with the DSP module (9p) and/or spectral decomposition module (7t) of the control unit (9) shown in FIGS. 2D, for detection of the single spin NMR signals/peaks in the received signals, and/or the ID (9i) and/or CIG (9g) modules of shown in FIGS. 2A and 2D, for identifying the atoms/molecules examined by the tunneling tip 13n based on the detected single spin NMR signals/peaks, and concurrently constructing a composite image from the ALI the single spin NMR peak data/signals. The single spin NMR measurement system 30 of FIG. 3A can be configured to use the ESR detector 7 of FIG. 1A, 2A or 2D.

If the tunneling tip 13n is part of a STM system 2, the operation of the STM system 2 can be separately controlled by the STM controller (15s optional, designated by dashed box lines). The STM controller 15s may be configured to receive a processed signal obtained by filtering the tunneling current signal Iₜ by the low pass filter (LPF 13f optional, shown in dashed box lines) configured to pass the alternating voltage signal of the sample electrode (13t), and convert the same into a voltage signal by the I-V converter (13c optional, shown in dashed box lines) for analysis by the STM controller 15s. The I-V converted signal is analysed by the STM controller 15s to control accordingly the distance of the tunneling tip 13n from the sample electrode 13t and construct the ALI for the examined sample 13s, as conventionally performed in STM systems.

As exemplified in FIG. 2C, in possible embodiments the initialization stage (step s1) is carried out using a predetermine externally applied static magnetic field B, and the frequency F_{b} of the alternating bias voltage V_{b} is swept (e.g., between 3 to 31 MHZ) by the function generator 13g to detect in step s2 the bias modulating frequency F_{b} for which the maximal (or observable) ESR hyperfine peak is obtained. It is desired in embodiments hereof that the magnetic field B induced through the sample 13s be of the same order of magnitude with the lateral hyperfine coupling i.e., the magnetic field that is applied by the electron on the nucleus, which is perpendicular to the external magnetic field B. This approach is however less favourable as it requires a tuneable impedance matching circuitry (step q10 in FIG. 2C) capable of tuning to each frequency F_{b} of the alternating bias voltage, as found in step s2, which substantially complicates the system design.

In some embodiments the system 30 may further includes two RF coils (C1 and C2 optional, indicated by dashed box lines) configured to apply electromagnetic RF pulse signals perpendicular of the direction of the applied magnetic field (B) for superposition single spin NMR measurements, which are detected by the modulated hyperfine ESR peak in the tunneling current Iₜ. Such RF coils (C1 and C2) can be similarly used in any of the embodiments described hereinabove with reference to FIGS. 2A and 2D e.g., in addition to the alternating ionization voltage. In addition, in possible embodiments the single spin NMR signal measurement system 30 of FIG. 3A comprises the PWM unit (13w), and/or the measurement chamber (13b), and/or the temperature control unit (13e), and/or the pressure control unit (13r), as shown and described herein above with reference to FIG. 2D.

The alternating bias/ionization voltage V_{b} has two main rolls: (i) to excite the nucleus to create a superposition of states which result in its precession; and (ii) to stream the tunneling current Iₜ used for measuring the nuclear precession through the hyperfine ESR peak signals of the unpaired electron. The RF coils C1 and C2 are used in possible embodiments for excitation of the nuclei precession i.e., in addition to the alternating ionization voltage, and might be more effective in doing so. RF signal generator 15g is used in some possible embodiments to drive the RF coils C1 and C2 e.g., responsive to control signals/data thereby received from the control unit 15.

STM systems 2 equipped with the single spin NMR precession signals measurement techniques/setups disclosed herein can be modified to generate composite images comprising the two-dimensional (2D) ALI of the examined sample (13s) combined with respective mapping of the single spin NMR peaks of each examined atom/molecule indicative of the chemical elements of the atom/molecule of the sample and/or its chemical environment, which can be used to identify the molecules from which the examined sample (13s) is composed. Accordingly, in some embodiments the system 30 is equipped with the CIG module 6g of FIG. 2A for concurrently receiving ALI pixels as they are generated in real-time by an electronic microscope (e.g., STM system 2) and match them with respective single spin NMR precession signals/peaks determined/detected by the system 30.

FIG. 3C schematically illustrates a composite image 33 according to some possible embodiments. As seen, the composite image 33 comprises an ALI layer 33a combined with a single spin NMR peak signals map 33n comprising respective single spin NMR spectra data Np for each atomic level pixel Ap of the ALI layer 33a. For example, the NMR peak signals map 33n may be configured to set a color map of the composite image 33 according to its NMR spectra data Np (e.g., in correspondence with atomic weights of identified atoms), and the atomic level pixels Ap of the ALI layer 33a can be configured to set intensities of the pixels.

### EXAMPLES

The presently disclosed subject matter will be described in greater detail by way of specific examples. The following examples are offered for illustrative purposes only and are not intended to limit the claimed invention in any manner. Those of skill in the art will readily recognize a variety of non-critical parameters that can be changed or modified to yield essentially the same/similar results.

### Example 1

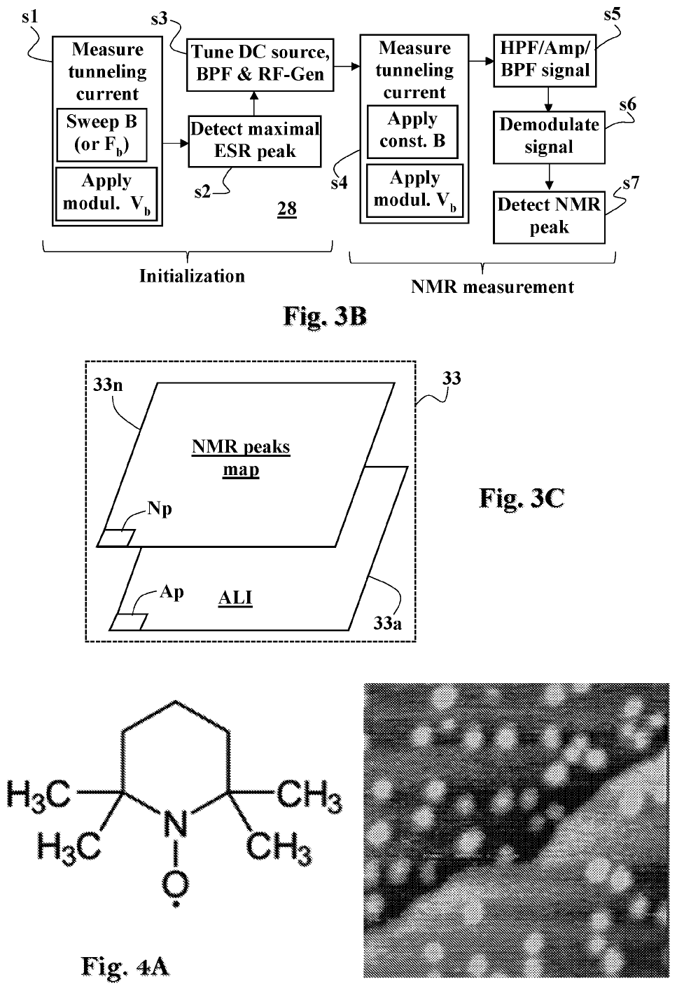

As a first example of the measurement technique disclosed herein a simpler experiment was carried out on a free radical sample material at a small bias voltage that becomes a diamagnetic ion upon ionization with a relatively larger bias voltage (V_{b}). For this purpose a TEMPO molecules were used, which were deposited on an Au(111) surface covered with graphene oxide (GO). FIG. 4A shows a STM image (right, 20×20 nm²) indicating separate TEMPO molecules examined on the Au(111) surface, and the atomic structure of the TEMPO radical molecule (right).

The second molecule tested in this example was toluene deposited on the same substrate. Toluene is known to have a ESR spectrum of its anion radical. FIG. 4B shows the atomic structure of the toluene molecule (left), and a STM image thereof (right) examined on the Au(111) surface.

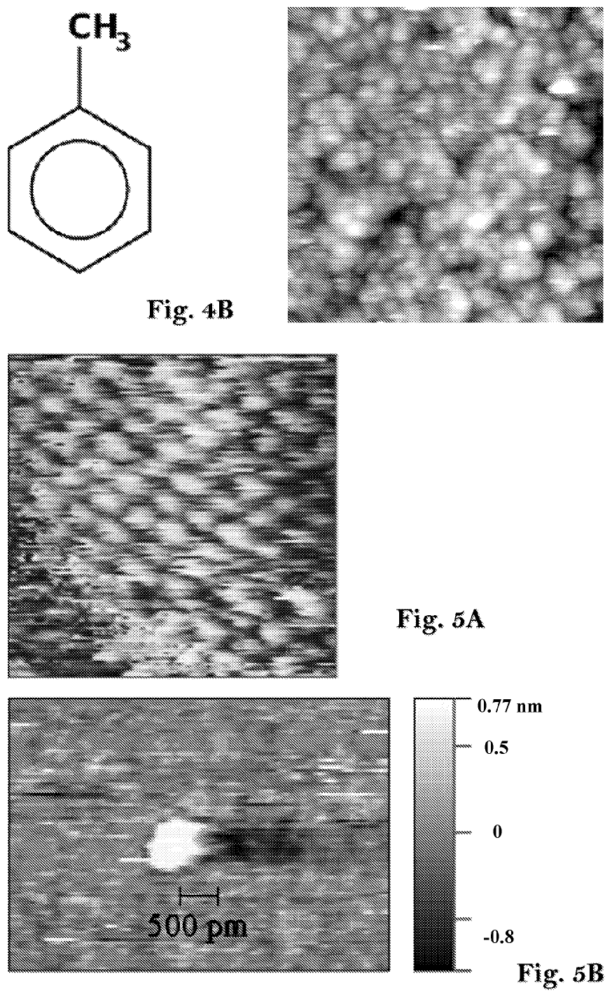

Next, it is demonstrated that relatively high bias voltage levels lead to ionization and formation of a spin state. The experiment was done on ⁶⁰C. molecules deposited on graphene by looking at a constant frequency of 300 MHz in the power spectrum of a tunneling current of a STM system, and sweeping the magnetic field B between 0 (zero) to 400 Gauss. The maximum observed in the spectrum of the tunneling current corresponds to resonance with g=300 MHz/(μB), where μB is the Bohr magneton. The data shows that above 1 (one) Volt a resonance near g=2 appears but is missing at 0.5 Volt. This demonstrates that the voltage leads to an ionized spin carrying state of ⁶⁰C. FIG. 5A shows STM image (17×17 Angstroms) of graphene without ⁶⁰C molecules, and FIG. 5B shows a STM image of a single ⁶⁰C molecule with a diameter of 0.7 nm [10].

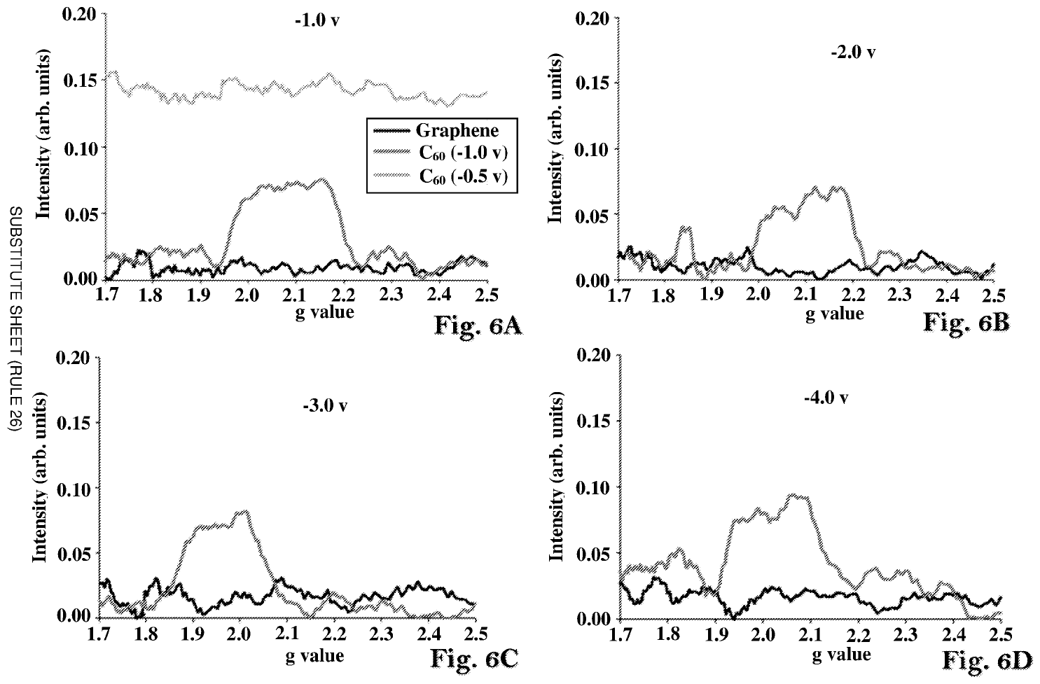

With reference to FIGS. 6A to 6D, demonstrating for spectra of ⁶⁰C molecules that the ionization is at the position (in energy) of the LUMO orbital of ⁶⁰C on graphene [11], as seen in FIGS. 6A-D, above 1 (one) Volt a resonance near g=2 appears but is missing at 0.5 Volt. This demonstrates that the voltage leads to an ionized spin carrying state of ⁶⁰C.

### Example 2

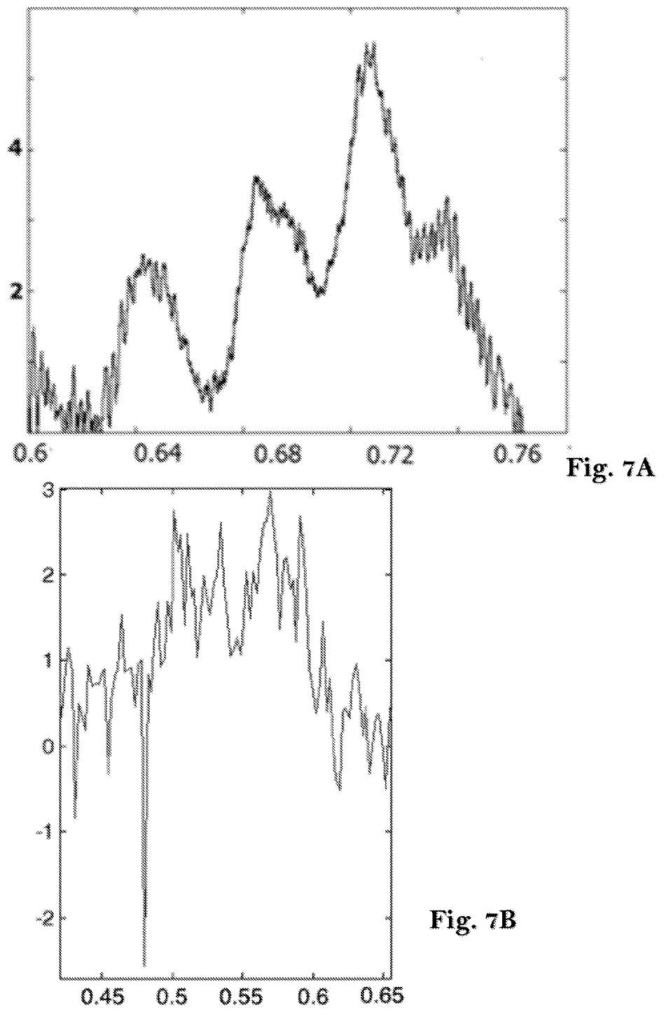

This example aims to demonstrate that the single molecule ESR-STM measurement hereof can indeed provide a detectable spectrum within substantially short time intervals. FIGS. 7A and 7B respectively show an ESR-STM spectrum (x-axes frequencies are in GHz) of a single TEMPO molecule acquired at 230 Gauss and time interval of 90 seconds, and an ESR-STM spectrum of the same molecule acquired at 186 Gauss and time interval of 0.1 second (derivative spectrum). FIGS. 7A and 7B show that a hyperfine ESR spectrum (although noisy) is detectable also within a short acquisition time intervals.

Next, NMR experiment results were obtained for ¹⁴N nucleus on a TEMPO molecule. Initially, the spectrum and the image were taken with a positive sample bias voltage of 0.2 Volt. Afterwards single spin NMR measurements were performed utilizing a spectrum analyser to analyse the spectrum of the hyperfine ESR signals/peaks observed in the tunneling current. For this measurement the spectrum analyser was set at a constant frequency at the center of the low frequency hyperfine peak. The bias voltage was oscillating between 0.2V to 3.7 volt at a frequency of 250 KHz. The video output of the spectrum analyser was recorded for magnetic field of 230 Gauss as a function of time with a bandwidth of 1 MHZ, and thereafter analysed by a lock in amplifier, in which the reference frequency was swept from 0 to 150 KHz.

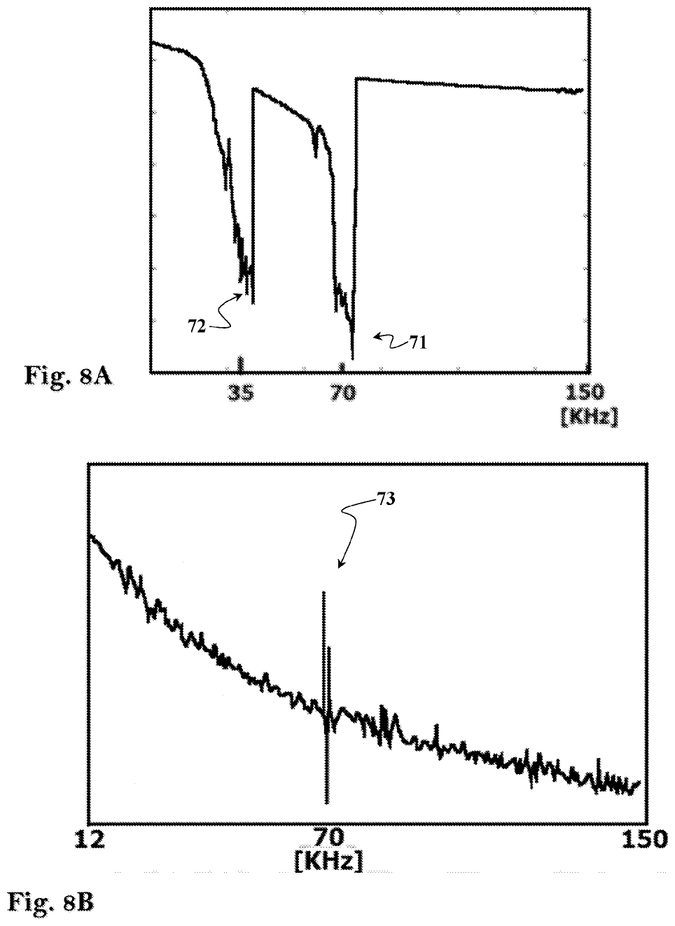

The measured single spin NMR spectrum observed from frequency modulation of the low frequency hyperfine peak shown in FIG. 8A reveal that a significant signal extremum (minimum peak) 71 was detected quite often in the NMR spectrum at 70 KHz, which is the Larmor frequency of the ¹⁴N nucleus at 230 Gauss. A clear peak/extremum 72 is also observed in the NMR spectrum shown in FIG. 8A in a frequency of half the nuclear Larmor frequency i.e., 35 KHz. These peaks/extremums appear in many NMR spectra, and as seen, the linewidth is much broader than that obtained in the macroscopic NMR peak/extremums.

In another experiment the spectrum analyser was set on the frequency of the central hyperfine peak of the ¹⁴N molecule. As seen in FIG. 8B, in this case a sharper NMR (extremum) line 73 is observed, without the half frequency peak/extremum.

### Example 3

The experiment that were done on toluene on Au(111) is an opposite experiment to what was done in TEMPO. Namely, in TEMPO the ionization due to a large bias voltage causes a disappearance of the para magnetism, while in toluene the ionization creates a paramagnetic radical anion. This experiment is more important since it demonstrates that single spin NMR is detectable also on nonmagnetic species. The atoms which can give an NMR signal is ¹H. The magnetic field in this experiment was set to 230G, for which the nuclear Larmor frequency of ¹H (gyromagnetic ratio of 42.6 MHz*T⁻¹) is 980 KHz.

### Example 4

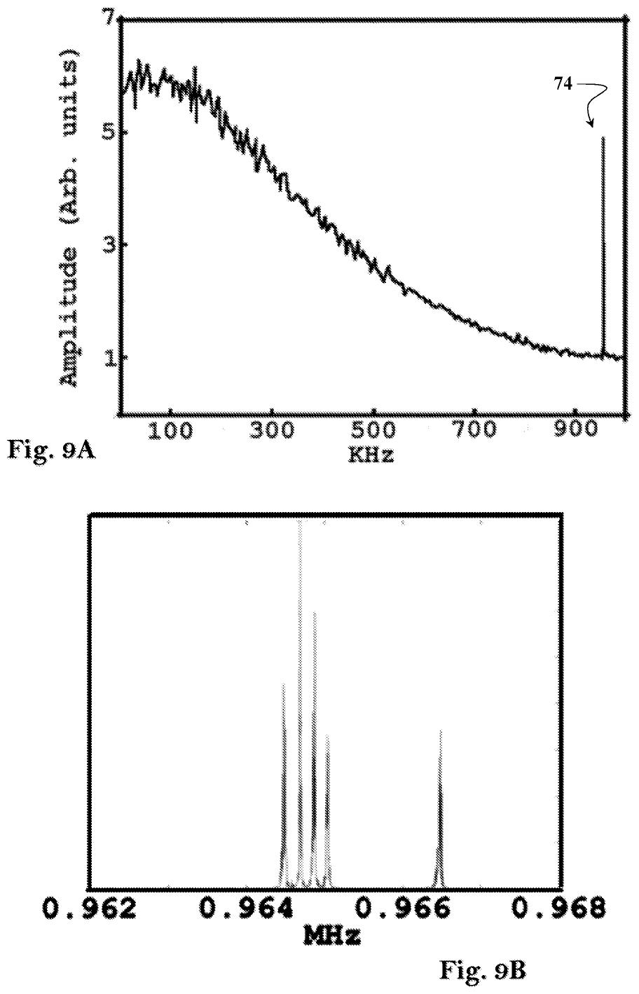

This example shows that higher resolution spectrum observation is possible utilizing by settings of the digital spectrum analyser with a large number of points. FIG. 9A depicts detection of a single spin NMR precession signal/peak 74 in NMR spectrum measured using techniques disclosed herein, showing the gyromagnetic ratio of ¹H in toluene. It is noted that the dwell time for NMR detection of the spectrum observed in FIG. 9A is 0.5·10⁻⁶ seconds, and that a 1 (one) second total acquisition time interval was used, which means that 2·10⁶ points been acquires (in time domain—for observing positive and negative frequencies from −1 MHZ to +1 MHz in the frequency domain). If the digital spectrum analyser is set for 288000 points (instead of the 1000 points used for the spectrum of FIG. 9A), the spectrum observed by focusing on the narrow peak of the ¹H hydrogen gyro magnetic ratio, is a high resolution spectrum. FIG. 9B shows high resolution single spin NMR spectrum enabling the identification of toluene in the single molecule level, which as can be seen, is comparable to the macroscopic spectrum shown in FIG. 9C for the same specimen.

Although there is a significant similarity with the microscopic ¹H spectrum of toluene, it is clear that the chemical shift and the J value (for coupling between neighbouring nuclei) scales by several orders of magnitude compared with the macroscopic spectrum. It is possible that this scaling phenomenon is due to the presence of the paramagnetic phase in part of the time. It is noted that in the earlier times of NMR spectroscopy, when the magnetic fields were much smaller then achieved nowadays, in order to separate between overlapping peaks, a common procedure was to add paramagnetic material(s) to the measured liquid samples (shift reagent [12]). This procedure scaled the chemical shifts by up to 2 (two) or 3 (three) order of magnitudes. The scaling of the J value is probably due to the dipolar interaction in a molecule with restricted motion, which results in a larger hyperfine splitting and does not appear in a liquid.

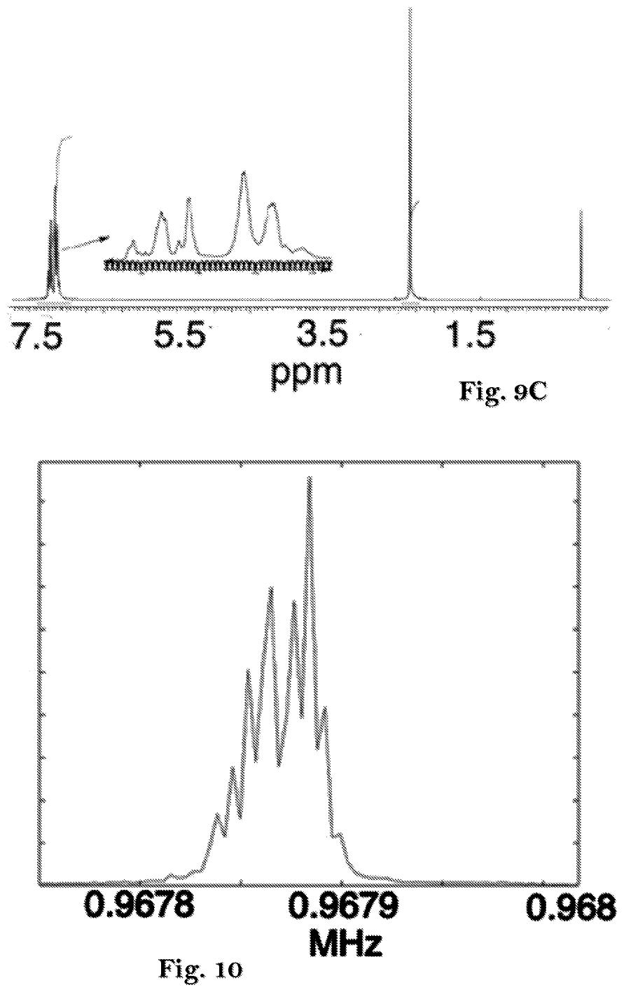

In many cases there is smaller scaling of the chemical shift and the spectrum of toluene looks different, for example, as seen in FIG. 10, wherein the aromatic peaks (6 in number) overlap with the aliphatic peaks. A possible explanation might be that since the molecules are not adsorbed in the same way on the surface, about ⅓ of the spectra are similar to spectrum in FIG. 9B, and the other ⅔ to the spectrum of FIG. 10.

These results obtained in the above-described examples demonstrate that single spin NMR spectrum can be measured using STM systems in different nuclei and different substrates, and indicate that proof of concept was achieved.

### Discussion

A model quantitatively explaining the above-described results (but not yet the scaling shown in FIGS. 9B and 10) will be now presented. The basic ingredient that allows time dependent hyperfine signal is the presence of a hyperfine tensor element that is perpendicular to the external magnetic field. To demonstrate this possibility, a simple model with nuclear spin ½ without relaxation is considered, that has a hyperfine component in the ‘Z’ direction (direction of the external magnetic field B), and another component in a perpendicular ‘X’ direction. It is assumed that the molecule is ionized during a time interval T, when it propagates with eigenvalues ±½ vₙ (without an electron spin), where vₙ is the nuclear Larmor frequency, and then deionized during a time interval T′ when the molecule is neutral (when the molecule acquires an electron spin).

In the presence of an electron spin size is neglected and the Hamiltonian is described by:

$$( \begin{matrix}\frac{1}{2} v + a & 0 & 0 & b \\ 0 & \frac{1}{2} v - a & b & 0 \\ 0 & b & - \frac{1}{2} v - a & 0 \\ b & 0 & 0 & - \frac{1}{2} v + a\end{matrix} )$$

where v is the electron Larmor frequency, a is the (parallel to the external field) hyperfine constant, and b the perpendicular hyperfine constant due to the anisotropic hyperfine contribution. Basis electron states and nuclear spins are used |↑±, ↑↓, ↓↑, ↓↓> (not ordered by their diagonal energies). Diagonalising the Hamiltonian gives the eigenvectors V₁, V₂, V₃ and V₄ and the eigenvalues λ₁, λ₂, λ₃, λ₄. During the time interval T in which the electron is away from the molecule, the 1^{st} and 3^{rd} components of either eigenvector evolve in time with e^{iv}^{ₙ}^{T}, while the 2^{nd} and 4^{th} components evolve with e^{-iv}^{ₙ}^{T}, where vₙ is the nuclear Larmor frequency; this generates the eigenvectors Vₖ(T), k=1,2,3,4. Afterwards, during the time interval T′ an electron spin is added to the molecule. The eigenvectors Vₖ(T) are then projected on a previous Vₘ and then propagate with the eigenvalues λₘ. Hence the states after the time interval T+T′ are Vm(T+T′)=ΣₖVₘ^{†}Vₖ(T)e^{iλ}^{ₘ}^{T′}Vₘ. This procedure is repeated for times (2T+2T′), (3T+3T′), etc. The result shows that the ESR transitions from states 1 to 3 or from 2 to 4 become time dependent with two frequencies that are related to vₙ. The precise relation depends on the residue of the ratio of v and the modulation frequency of the alternating bias voltage F_{b}=1/(T+T′). The difference of the two frequencies is 2vₙ. In the special case where the residue vanishes the two frequencies are ±vₙ.

As an example, the ¹H results on toluene shown hereinabove (FIGS. 9 and 10) are done with a measured ESR frequency of 627 MHz and with a modulation frequency of F_{b}=15.675 MHz i.e., vanishing residue if T=T′. One should aim to explore the deviation from the nuclear Larmor frequency as function of a deviation from the modulation frequency F_{b}=15.675 MHZ that would test the model. The data shows that the high-resolution spectra appears only when the condition of vanishing residue is fulfilled.

The above examples demonstrate a successful observation of single spin NMR spectrum, which was detected experimentally and explained theoretically, and that a clear single spin NMR spectrum can be achieved within one second-which is close to the time that a (slow) scan of STM takes to record 1 pixel. This means that the possibility to observe an atomically resolved STM image with the identification of each atom based on single spin NMR spectrum measurement techniques/embodiments on the present application, is feasible.

Several possibilities to improve the performance of the techniques disclosed herein are to cool down the temperature of the experiment setup, to change the ratio between the size of the externally applied magnetic field B and the anisotropic hyperfine constant. Another possibility is to separate between the role of the coupled electron spin as a detector and its role as a transmitter to excite the nucleus and to create its precession. This can be done by exciting the nuclei by electromagnetic RF fields that are synchronized with the ionization bias voltage pulses V_{b}. Such a modification can be used for quantum computation based on single spin NMR measurement techniques.

Another hurdle is the exploitation of single spin NMR signal measurements is the necessity to know what is the spectrum of single spin ESR of each examined atom or molecule. A possible solution for such a limitation is to detect the hyperfine coupling between an electron spin of the tip and a nuclear spin on the surface, and configure the control unit (e.g., STM controller 15s in FIG. 3A) to change the tunneling distance in order to detect a single spin NMR spectrum for an unknown (a priory) spins. Another possibility is to observe the NMR signal at different ESR frequencies (627 MHZ in the above examples) with the corresponding modulation frequencies (627/40 in the above examples). An NMR peak with a large (i.e., observable) amplitude will indicate the presence of a hyperfine peak. A zero amplitude will indicate that at this ESR frequency there is no hyperfine peak of the ionized molecule.

It is noted that the techniques disclosed herein depend on fast and smooth temporal ionization of very different species, which may depend on the specific STM substrate, the insulating layers, the vacuum and temperature conditions, etc.

Relative terms such as “lower,” “upper,” “horizontal,” “vertical,” “above,” “below,” “up.” “down,” “top” and “bottom”, as well as derivatives thereof (e.g., “horizontally,” “downwardly.” “upwardly,” etc.), and similar adjectives in relation to orientation of the described elements/components refer to the manner in which the illustrations are positioned on the paper, not as any limitation to the orientations in which these elements/components can be used in actual applications.

It should also be understood that throughout this disclosure, where a process or method is shown or described, the steps/acts of the method may be performed in any order and/or simultaneously, and/or with other steps/acts not-illustrated/described herein, unless it is clear from the context that one step depends on another being performed first. In possible embodiments not all of the illustrated/described steps/acts are required to carry out the method. The disclosed methods can be implemented as program code stored on an article of manufacture e.g., program instructions and/or data stored on storage media and executable by a computer device, to facilitate implement the method by computing devices. In an embodiment where the invention is implemented using software, the software can be stored in a computer program product and loaded into the computer system using a removable storage drive, a memory chip, or a communication interface. The control logic (software), when executed by a control processor, causes the control processor to perform certain functions of the invention as described herein.

Aspects of the present disclosure may be embodied as a system, method or computer program product. Accordingly, aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.”

In possible embodiments, features of the disclosed embodiments are implemented primarily in hardware using, for example, hardware components such as application specific integrated circuits (ASICs) or field-programmable gated arrays (FPGAs). Implementation of the hardware state machine so as to perform the functions described herein will be apparent to persons skilled in the relevant art(s).

As described hereinabove and shown in the figures, the present invention provides techniques and setups/systems for single spin NMR precession signal measurement and related methods. While particular embodiments of the invention have been described, it will be understood, however, that the invention is not limited thereto, since modifications may be made by those skilled in the art, particularly in light of the foregoing teachings. As will be appreciated by the skilled person, the invention can be carried out in a great variety of ways, employing more than one technique from those described above, all without exceeding the scope of the claims.

1. A single spin nucleus resonance (NMR) detector comprising:
a pulse generator configured to apply an alternating bias voltage to a tunneling tip in a frequency at least greater than an NMR frequency range and smaller than a hyperfine electron spin resonance (ESR) frequency range for alternatingly changing within each cycle of said alternating bias voltage at least one atom or molecule of a sample material between diamagnetic and paramagnetic states, said sample material is placed on a sample electrode while a static uniform magnetic field of a determined strength is induced through it;
a hyperfine ESR detector configured to measure an electrical tunneling current passing through said sample electrode in response to each cycle of said alternating bias voltage, identify in said electrical tunneling current a plurality of hyperfine ESR signals/peaks, each associated with a respective cycle of said alternating bias voltage, and determine a hyperfine ESR frequency thereof; and
a NMR analyzer configured to identify in said plurality of hyperfine ESR signals/peaks at least one single spin NMR precession signal/peak based on changes in said plurality of hyperfine ESR signals/peaks.

2. The detector of claim 1 comprising a tuneable magnetic field applicator configured to induce the uniform magnetic field through the sample electrode, said detector is configured to adjust said uniform magnetic field for detection of at least one distinguishably strong hyperfine ESR signal/peak by the ESR detector.

3. The detector of claim 1 configured to set at least one of the following such that a ratio of the hyperfine ESR frequency detected by the ESR detector and a frequency of the alternating bias voltage substantially equals a positive whole number: (i) a strength of the magnetic field induced through the sample by a tuneable magnetic field applicator; or (ii) time interval of the cycles of the alternating bias voltage generated by the pulse generator.

4. (canceled)

5. The detector of claim 1 comprising a band-pass filter configured to extract from the electrical tunneling current a band-pass signal, and wherein the ESR detector is configured to identify in said band-pass signal the plurality of hyperfine ESR signals/peaks, and/or tune the band-pass filter to a frequency band determined based on the hyperfine ESR frequency of at least one of the plurality of hyperfine ESR signals/peaks identified in the electrical tunneling current.

6. (canceled)

7. The detector of claim 1 comprising at least one of the following: a peak detector in the ESR detector configured to detect the at least one hyperfine ESR signal/peak and determine a hyperfine ESR frequency thereof; a spectral decomposition unit configured to provide a spectral representation of the measured tunneling current for the identification of the plurality of hyperfine ESR signals/peaks and their respective hyperfine ESR frequencies; an identification module configured to identify a chemical element for the examined atom based on a frequency of the identified at least one single spin NMR precession signal/peak; one or more RF coils configured to apply electromagnetic irradiation to the examined sample; a pulse width modulation controller configured for adjusting time intervals of low and high state outputs of the alternating bias voltage generated by the pulse generator; a temperature control unit configured to adjust a temperature of the sample for improving detection by the ESR detector and/or the NMR analyzer; a pressure control unit configured to adjust pressure conditions in a volume containing the sample for improving detection by the ESR detector and/or the NMR analyzer.

8. (canceled)

9. The detector of claim 1 comprising a demodulator configured to demodulate the tunneling current using the hyperfine ESR frequency determined by the ESR detector for at least one of the plurality of hyperfine ESR signals/peaks and generate a demodulated signal thereof, and a peak detector configured to detect at least one single spin NMR precession signal/peak in the demodulated signal from the demodulator.

10. (canceled)

11. (canceled)

12. The detector of claim 1 comprising a composite image generator configured to concurrently receive at least one pixel of an atomic level image of the sample and combine it with respective data associated with the identified at least one single spin NMR precession signal/peak for generating a composite image of atomic level and NMR precession data/signals.

13. (canceled)

14. (canceled)

15. (canceled)

16. (canceled)

17. The detector of claim 1 wherein the tunneling tip is part of a scanning tunneling microscope (STM).

18. The detector of claim 1 comprising a tuneable magnetic field applicator and a control unit configured to operate said pulse generator, the tuneable magnetic field applicator, and the ESR detector, to carry out an initialization procedure for scanning a predetermined range of magnetic field strengths induced by said tuneable magnetic field applicator through the sample material while applying the alternating bias voltage to the tunneling tip to identify by the ESR detector at least one hyperfine ESR peak/signal and determine its hyperfine ESR frequency.

19. The detector of claim 18 wherein the control unit is configured to tune a frequency of the pulse generator such that a ratio of the determined hyperfine ESR frequency and the tuned frequency of the pulse generator substantially equals a whole positive number.

20. The detector of claim 1 comprising a magnetic field applicator and a control unit configured to operate said pulse generator, the magnetic field applicator, and the ESR detector, to carry out an initialization procedure for scanning a predetermined range of frequencies of the alternating bias voltage applied by said pulse generator to the tunneling tip while a predetermined magnetic field is induced by said magnetic field applicator through the sample material to identify by the ESR detector at least one hyperfine ESR signal/peak and determine its hyperfine ESR frequency.

21. The detector of claim 17 comprising a control unit configured to carry out one or both of the following: tune the NMR analyzer to identify the plurality of hyperfine ESR signals/peaks within a frequency range defined based on the hyperfine ESR frequency of the identified at least one hyperfine ESR signal/peak; control operation of said detector and of an STM for simultaneously generating by the STM a pixel of an atomic level image of the sample material placed on the sample electrode and identifying a respective at least one single spin NMR precession signal/peak.

22. (canceled)

23. A single spin nucleus resonance (NMR) measurement system comprising:
a sample electrode configured to hold sample material thereon at a determined reference voltage level;
a tunneling tip configured for adjustable placement in close proximity to said sample electrode and effect an electrical tunneling current therethrough;
a pulse generator configured to apply an alternating bias voltage to said tunneling tip in a frequency at least greater than an NMR frequency range and smaller than a hyperfine ESR frequency range for alternatingly changing at least one atom or molecule of said sample material between diamagnetic and paramagnetic states;
a magnetic field applicator configured to induce a magnetic field of a determined strength through said at least one atom or molecule of the sample;
a hyperfine ESR detector configured to identify in said electrical tunneling current a plurality of hyperfine ESR signals/peaks and determine a hyperfine ESR frequency thereof; and
a NMR analyzer configured to identify at least one single spin NMR precession signal/peak based on changes in said plurality of hyperfine ESR signals/peaks.

24. The system of claim 23 comprising a control unit configured to carry out at least one of the following: an initialization procedure for scanning a predetermined range of magnetic field strengths induced by the tuneable magnetic field applicator through the sample material while applying the alternating bias voltage to the tunneling tip to identify by the ESR detector at least one hyperfine ESR peak/signal and determine its hyperfine ESR frequency; tune a frequency of the pulse generator such that a ratio of the determined hyperfine ESR frequency and the tuned frequency of the pulse generator substantially equals a whole positive number; carry out an initialization procedure for scanning a predetermined range of frequencies of the alternating bias voltage applied by said pulse generator to the tunneling tip while a predetermined magnetic field is induced by said magnetic field applicator through the sample material to identify by the ESR detector at least one hyperfine ESR signal/peak and determine its hyperfine ESR frequency; tune the NMR analyzer to identify the plurality of hyperfine ESR signals/peaks within a frequency range defined based on the hyperfine ESR frequency of the identified at least one hyperfine ESR signal/peak.

25. (canceled)

26. (canceled)

27. (canceled)

28. The system of claim 24 wherein the control unit is configured to control operation of the system and of an STM for simultaneously generating by the STM at least one pixel of an atomic level image of the atom or molecule of the sample material placed on the sample electrode and identifying its at least one single spin NMR precession signal/peak.

29. A single spin nucleus resonance (NMR) measurement method comprising:
inducing a static uniform magnetic field of a determined strength through a sample material placed on a sample electrode;
applying an alternating bias voltage to a tunneling tip in a frequency at least greater than an NMR frequency range and smaller than a hyperfine electron spin resonance (ESR) frequency range for alternatingly changing within each cycle of said alternating bias voltage at least one atom or molecule of a sample material between diamagnetic and paramagnetic states;
measuring an electrical tunneling current passing through said sample electrode in response to each cycle of said alternating bias voltage;
identifying in said electrical tunneling current a plurality of hyperfine ESR signals/peaks, each associated with a respective cycle of said alternating bias voltage, and determine a hyperfine ESR frequency thereof; and
identifying at least one single spin NMR precession signal/peak based on changes in said plurality of hyperfine ESR signals/peaks.

30. The method of claim 29 comprising tuning at least one of a strength of the magnetic field induced through the sample, or time interval of cycles of the alternating bias voltage, such that a ratio of the hyperfine ESR frequency detected by the ESR detector and a frequency of the alternating bias voltage substantially equals a positive whole number.

31. (canceled)

32. The method claim 29 comprising extracting from the electrical tunneling current a band-pass signal and identifying the plurality of hyperfine ESR signals/peaks in said band-pass signal.

33. The method of claim 32 comprising tuning the extraction of the band-pass signal to a frequency band determined based on the hyperfine ESR frequency of at least one of the plurality of hyperfine ESR signals/peaks.

34. The method of claim 29 comprising performing spectral decomposition to the measured tunneling current for the identifying of the plurality of hyperfine ESR signals/peaks and their respective hyperfine ESR frequencies.

35. The method of claim 29 comprising demodulating the tunneling current using the hyperfine ESR frequency determined for at least one of the plurality of hyperfine ESR signals/peaks and detecting at least one single spin NMR precession signal/peak in a demodulated signal thereby generated.

36. (canceled)

37. The method of claim 29 comprising identifying a chemical element for the examined atom based on a frequency of the identified at least one single spin NMR precession signal/peak.

38. The method of claim 29 comprising generating a composite image comprising at least one pixel of an atomic level image of the sample and respective data indicative of the identified at least one single spin NMR precession signal/peak.

39. The method of claim 29 comprising at least one of the following: applying electromagnetic irradiation to the examined sample; adjusting time intervals of low and high state outputs of the alternating bias voltage generated by the pulse generator; adjusting a temperature of the sample for improved identification of the hyperfine ESR signals/peaks; adjusting pressure conditions in a volume containing the sample for improved identification of the hyperfine ESR signals/peaks.

40. (canceled)

41. (canceled)

42. (canceled)

43. The method of claim 29 comprising carrying out an initialization procedure for at least one of the following: scanning a predetermined range of magnetic field strengths induced through the sample material while applying the alternating bias voltage to the tunneling tip and identifying at least one hyperfine ESR peak/signal and determining its hyperfine ESR frequency; scanning a predetermined range of frequencies of the alternating bias voltage applied to the tunneling tip while applying a predetermined magnetic field through the sample material and identifying at least one hyperfine ESR signal/peak and determining its hyperfine ESR frequency.

44. The method of claim 43 comprising tuning a frequency of the alternating bias voltage such that a ratio of the determined hyperfine ESR frequency and the tuned frequency of the alternating bias voltage substantially equals a whole positive number.

45. (canceled)

46. The method of claim 43 comprising identifying the plurality of hyperfine ESR signals/peaks within a frequency range defined based on the hyperfine ESR frequency of the identified at least one hyperfine ESR signal/peak.

47. A composite image comprising at least one pixel of an atomic level image of a sample, and data indicative of single spin NMR precession signal/peak associated with said at least one pixel, wherein the single spin NMR precession signal/peak is identified utilizing the detector of any one of claim 1.

48. (canceled)
